(19) United States
(12) Patent Application Publication
(10) Pub. No.: US 2013/0319529 A1
(43) Pub. Date: Dec. 5, 2013

(54) PHOTOELECTRIC CONVERSION ELEMENT, METHOD FOR PRODUCING PHOTOELECTRIC CONVERSION ELEMENT, AND ELECTRONIC EQUIPMENT

(71) Applicants: Ryohei Tsuda, Kanagawa (JP); Masahiro Morooka, Kanagawa (JP)

(72) Inventors: Ryohei Tsuda, Kanagawa (JP); Masahiro Morooka, Kanagawa (JP)

(73) Assignee: Sony Corporation, Tokyo (JP)

(21) Appl. No.: 13/984,636

(22) PCT Filed: Feb. 10, 2012
(86) PCT No.: PCT/JP2012/053734

§ 371 Date: Aug. 9, 2013

(30) Foreign Application Priority Data
Mar. 2, 2011 (JP) 2011-044911

(51) Int. Cl. H01G 9/20; H01L 31/18

(52) U.S. Cl. CPC H01G 9/2004; H01L 31/18
USPC 136/263; 438/93; 136/252

(57) ABSTRACT

A photoelectric conversion element has a structure in which an electrolyte layer having an electrolyte solution is disposed between a porous electrode and a counter electrode. At least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is added to the electrolyte solution. In a dye-sensitized photoelectric conversion element, a photosensitizing dye is bonded to the surface of the porous electrode.

### TECHNICAL FIELD

The present disclosure relates to a photoelectric conversion element, a method for producing a photoelectric conversion element, and an electronic equipment. For example, the invention relates to a photoelectric conversion element suitable for use in dye-sensitized solar cell, a method for producing the photoelectric conversion element, and an electronic equipment using the photoelectric conversion element.

### BACKGROUND ART

A solar cell as a photoelectric conversion element operable to convert sunlight into electrical energy uses the sunlight as a source of energy. Therefore, the solar cell has extremely little influence on global environments and, hence, is expected to be used more widely.

As the solar cells, those which have been mainly used are crystal-silicon solar cells, using single crystal silicon or polycrystalline silicon, and amorphous-silicon solar cells.

On the other hand, the dye-sensitized solar cell proposed by Gratzel et al. in 1991 has been paid attention to since it can exhibit a high photoelectric conversion efficiency and, unlike conventional silicon solar cells, it can be produced at low cost without needing a large-scale equipment (see, for example, Non-Patent Document 1).

The dye-sensitized solar cell, in general, has a structure in which a porous electrode formed of oxide titanium or the like with a photosensitizing dye bonded thereto and a counter electrode formed of platinum or the like are disposed to face each other, and the space between these electrodes is filled with an electrolyte layer having an electrolyte solution. As the electrolyte solution, solutions prepared by dissolving in a solvent an electrolyte including oxidation-reduction species such as iodine and iodide ion are frequently used.

As an additive for the electrolyte solution which improves the initial photoelectric conversion efficiency of the dye-sensitized solar cell, guanidinium thiocyanate (GuSCN) has been known (see Non-Patent Document 2).

### CITATION LIST

### Patent Document

Non-Patent Document 1: Nature, 353, p. 737-740, 1991
Non-Patent Document 2: Journal of Physical Chemistry B 2008, 112, 13775-13781
Non-Patent Document 3: Inorg. Chem. 1996, 35, 1168-1178
Non-Patent Document 4: J. Chem. Phys. 124, 184902 (2006)

### SUMMARY OF THE INVENTION

### Problems to be Solved by the Invention

However, according to the studies of the present inventors, it has been found that there is a problem that a dye-sensitized solar cell obtained by adding GuSCN to an electrolyte solution is subjected to the durability test in a dark place at 85° C., resulting in great reduction in durability.

A problem to be solved by the present disclosure is to provide a photoelectric conversion element such as a dye-sensitized solar cell which can achieve an improvement in durability.

Another problem to be solved by the present disclosure is to provide a method for producing a photoelectric conversion element which can produce a photoelectric conversion element having high durability.

Another problem to be solved by the present disclosure is to provide a high-performance electronic equipment obtained by using the excellent photoelectric conversion element.

These problems and other problems will be apparent from the description of the following specification with reference to the attached drawings.

### Solutions to Problems

In order to solve the above problems, the present disclosure relates to a photoelectric conversion element comprising a structure in which an electrolyte layer is formed between a porous electrode and a counter electrode, in which at least one first additive selected from the group consisting of GuOTf (guanidinium trifluorosulfonate), EMImSCN (1-ethyl-3-methylimidazolium thiocyanate), EMImOTf (1-ethyl-3-methylimidazolium trifluorosulfonate), EMImTFSI (1-ethyl-3-methylimidazolium bis(trifluoromethanesulfonyl)imide)), EMImTfAc (1-ethyl-3-methylimidazolium trifluoroacetate), EMImDINHOP (1-ethyl-3-methylimidazolium dineohexylphosphinate), EMImMeSO₃ (1-ethyl-3-methylimidazolium methylsulfonate), EMImDCA (1-ethyl-3-methylimidazolium dicyanoamide), EMImBF₄ (1-ethyl-3-methylimidazolium tetrafluoroborate), EMImPF₆ (1-ethyl-3-methylimidazolium hexafluorophosphate), EMImFAP (1-ethyl-3-methylimidazolium tris(pentafluoroethyl)trifluorophosphate), EMImEt₂PO₄ (1-ethyl-3-methylimidazolium diethylphosphate), and EMImCB₁₁H₁₂ (1-ethyl-3-methylimidazolium 1-carba-closo-dodecaborate) is added to the electrolyte layer.

The cation and anion constituting the first additive have the following chemical structures.

### (1) Cation

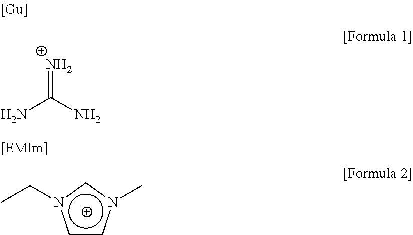

### (2) Anion

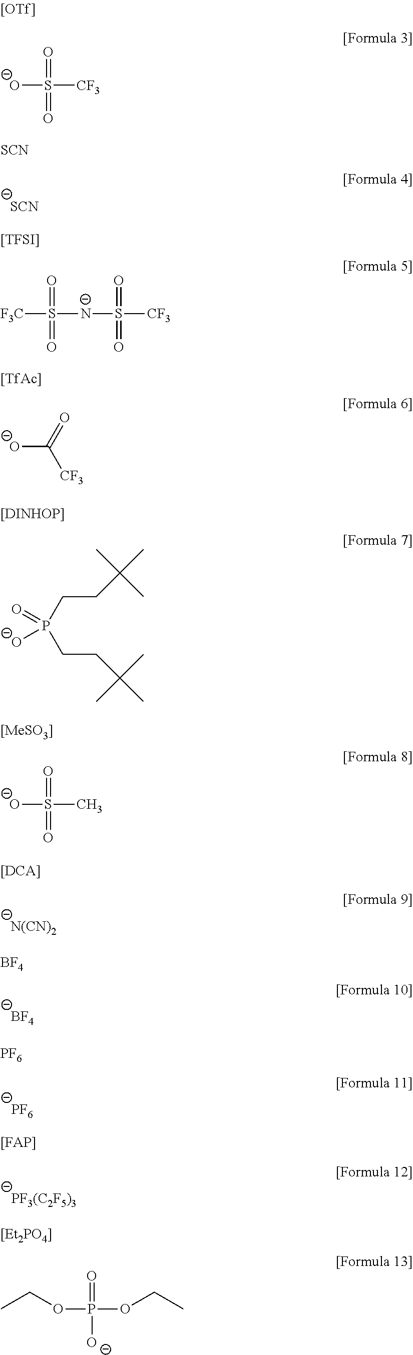

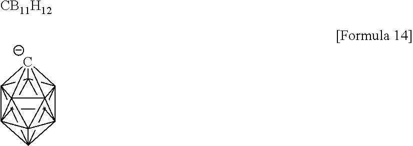

Further, the present disclosure relates to a method for producing a photoelectric conversion element comprising forming a structure in which an electrolyte layer to which at least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is added is formed between a porous electrode and a counter electrode.

Further, the present disclosure relates to an electronic equipment comprising at least one photoelectric conversion element, wherein the photoelectric conversion element has a structure in which an electrolyte layer is formed between a porous electrode and a counter electrode, and at least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is added to the electrolyte layer.

Further, the present disclosure relates to a photoelectric conversion element comprising a structure in which an electrolyte layer is formed between a porous electrode and a counter electrode, wherein at least one of first additives having one of cations represented by Formula (1), (2) or (3) below and anions below is added to the electrolyte layer.

### (1) Cation

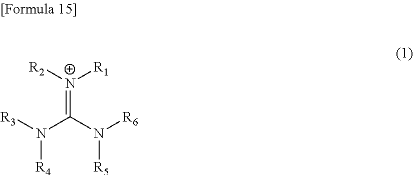

R₁ to R₆═H, or a hydrocarbon having 1 to 20 carbon(s)

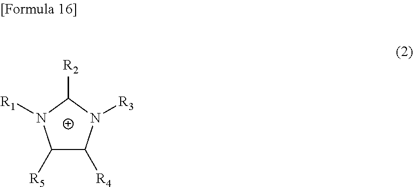

R₁ to R₅═H, or a hydrocarbon having 1 to 20 carbon(s)

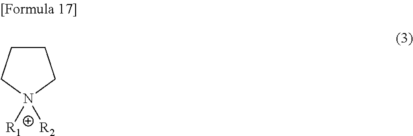

R₁ to R₂═H, or a hydrocarbon having 1 to 20 carbon(s)

### (2) Anion

SCN, [DCA], BF₄, PF₆, [TfAc], [OTf], [TFSI], [MeSO₃], [MeOSO₃], [HSO₄], [FAP], [DA], [DPA], [DINHOP], [FSI], [DEPA], [cheno], [Et₂PO₄], CB₁₁H₁₂, [COSAN], [cyclicTFSI], C₂F₅SO₃, C₃F₇SO₃, C₄F₉SO₃, N(C₃F₇SO₂)₂, N(C₄F₉SO₂)₂, fluorine, chlorine, bromine, and iodine.

An example of the cation represented by Formula (3) above is as follows.

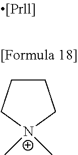

The chemical structure of the anion except [OTf], SCN, [TFSI], [TfAc], [DINHOP], [MeSO₃], [DCA], BF₄, PF₆, [FAP], [Et₂PO₄], and CB₁₁H₁₂ in the anion constituting the first additive is as follows.

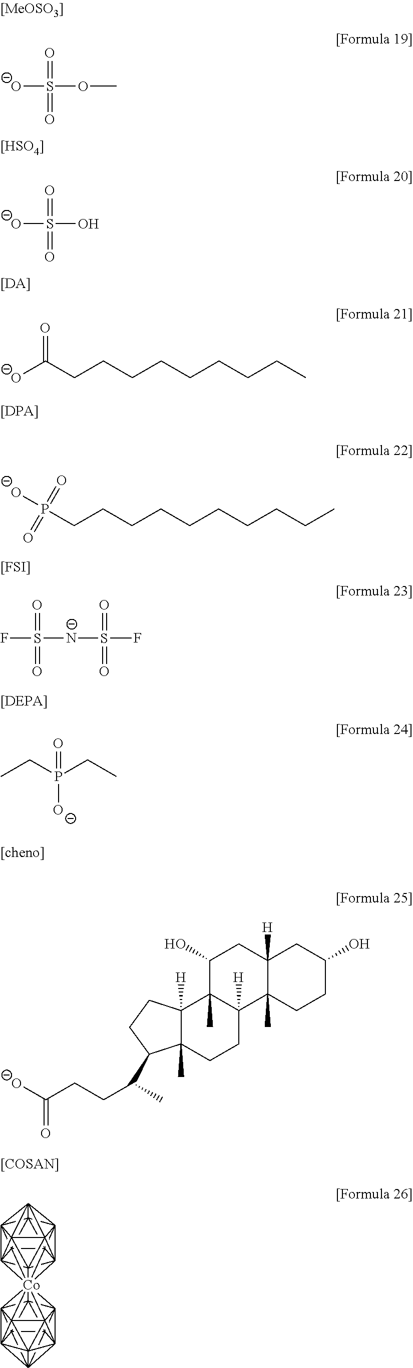

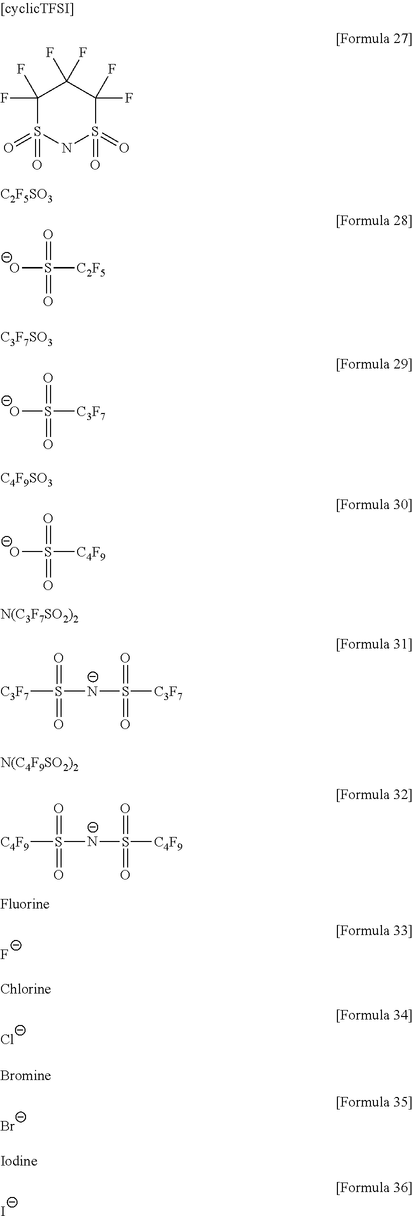

The photoelectric conversion element, typically, is a dye-sensitized photoelectric conversion element in which a photosensitizing dye is bonded to (or adsorbed on) a porous electrode. In this case, the method for producing the photoelectric conversion element, typically, further includes bonding the photosensitizing dye to the porous electrode. The porous electrode includes particles of a semiconductor. The semiconductor suitably includes titanium oxide (TiO₂), particularly, anatase type TiO₂.

As the porous electrode, one having particles of a so-called core-shell structure may be used; in this case, the photosensitizing dye may not necessarily be bonded. As the porous electrode, suitably, one having particles, each of which includes a core having a metal and a shell having a metal oxide surrounding the core is used. Use of such a porous electrode ensures that, in the case where the electrolyte layer having the porous film containing the electrolyte solution is provided between the porous electrode and the counter electrode, the electrolyte of the electrolyte solution does not make contact with the metal core of the metal/metal oxide particles, so that the porous electrode can be prevented from being dissolved by the electrolyte. Therefore, as the metal constituting the cores of the metal/metal oxide particles, the metals which have a high surface plasmon resonance effect and which have been difficult to use, such as gold (Au), silver (Ag), and copper (Cu). This enables the surface plasmon resonance effect to be sufficiently obtained in the photoelectric conversion. Further, an iodine electrolyte can be used as the electrolyte of the electrolyte solution. Platinum (Pt), palladium (Pd) and the like can also be used as the metal constituting the cores of the metal/metal oxide particles. As the metal oxide constituting the shells of the metal/metal oxide particles, a metal oxide which is insoluble in the electrolyte used is used and selected if necessary. As the metal oxide, suitably, at least one metal oxide selected from the group consisting of titanium oxide (TiO₂), tin oxide (SnO₂), niobium oxide (Nb₂O₅), and zinc oxide (ZnO) is used, however it is not limited thereto. For example, metal oxides such as tungsten oxide (WO₃) and strontium titanate (SrTiO₃) can also be used. The particle diameter of fine particles is appropriately selected and is suitably 1 to 500 nm. Further, the particle diameter of the core of the fine particles is appropriately selected and is suitably 1 to 200 nm.

The photoelectric conversion element, most typically, is configured as a solar cell. However, the photoelectric conversion element may also be other than a solar cell; for example, it may be a photosensor or the like.

The electronic equipment, basically, may be any of various electronic apparatuses, which include both portable ones and stationary ones. Specific examples of the electronic apparatus include portable phones, mobile apparatuses, robots, personal computers, on-vehicle apparatuses, and various home electronics. In this case, the photoelectric conversion element is, for example, a solar cell for use as power supply in the electronic equipment.

By the way, the electrolyte layer is typically composed of an electrolyte solution. Generally, an additive is added to the electrolyte solution in order to prevent reverse movement of electrons from the porous electrode into the electrolyte solution. As the additive, the best known is 4-tert-butylpyridine (TBP). The number of the kinds of additives for the electrolyte solution has been limited, the choice of the additives has been extremely narrow, and the degree of freedom in designing the electrolyte solution has been low. In view of this, the present inventors earnestly made experimental and theoretical studies with the intention of expanding the range of choices for the additives. As a result, it has been found that there are many additives which, when added to the electrolyte solution, can give more excellent characteristics than those of 4-tert-butylpyridine generally used in the past. Specifically, it has been concluded that more excellent properties than those obtained by using 4-tert-butylpyridine can be obtained by using an additive which has a pKₐ in the range of 6.04 to 7.03 (i.e., 6.04≦pKₐ≦7.3). In order to achieve this, a second additive having a pKₐ in the range of 6.04≦pKₐ≦7.3 is added to the electrolyte solution and/or a second additive having a pKₐ in the range of 6.04≦pKₐ≦7.3 is adsorbed on the surface of at least one of the porous electrode and the counter electrode. This makes it possible to obtain a photoelectric conversion element in which the range of choices for additives for an electrolyte solution is expanded and more excellent characteristics can be obtained, as compared with the case where 4-tert-butylpyridine is used as an additive.

The additive which is added to the electrolyte solution or is adsorbed on the surface of at least one of the porous electrode and the counter electrode may fundamentally be any substance, insofar as the substance has a pKₐ in the range of 6.04≦pKₐ≦7.3. Here, Kₐ is the equilibrium constant in dissociation equilibrium of a conjugate acid in water. The second additive is typically a pyridine-based additive or an additive having a heterocyclic ring.

Specific examples of the pyridine-based additive include 2-aminopyridine (2-NH2-Py), 4-methoxypyridine (4-MeO-Py), and 4-ethylpyridine (4-Et-Py), but they are not limited thereto. Specific examples of the additive having a heterocyclic ring include N-methylimidazole (MIm), 2,4-lutidine (24-Lu), 2,5-lutidine (25-Lu), 2,6-lutidine (26-Lu), 3,4-lutidine (34-Lu), and 3,5-lutidine (35-Lu), but they are not limited thereto. The additive is comprised of, for example, at least one selected from the group consisting of 2-aminopyridine, 4-methoxy pyridine, 4-ethylpyridine, N-methylimidazole, 2,4-lutidine, 2,5-lutidine, 2,6-lutidine, 3,4-lutidine, and 3,5-lutidine. Incidentally, compounds having in the molecule thereof a structure of a pyridine or heterocyclic compound with a pKₐ in the range of 6.04≦pKₐ≦7.3 are expected to be able to produce the same effect as that of the above additives with a pKₐ in the range of 6.04≦pKₐ≦7.3.

In order to adsorb the second additive on a surface of at least one of the porous electrode and the counter electrode (on the interface between the porous electrode or the counter electrode and the electrolyte layer, after the electrolyte layer is provided between the porous electrode and the counter electrode), it is sufficient to bring the second additive into contact with the surface of the porous electrode or the counter electrode by using the additive itself, an organic solvent containing the second additive, an electrolyte solution containing the second additive, or the like, before the electrolyte layer is provided between the porous electrode and the counter electrode. Specifically, it is sufficient, for example, that the porous electrode or the counter electrode is immersed in an organic solvent containing the second additive or that an organic solvent containing the second additive is sprayed onto the surface of the porous electrode or the counter electrode.

When the second additive is used, the molecular weight of the solvent of the electrolyte solution is suitably 47.36 or more. Examples of the solvent include nitrile solvents such as 3-methoxypropionitrile (MPN), methoxyacetonitrile (MAN), acetonitrile (AN), and valeronitrile (VN), carbonate solvents such as ethylene carbonate and propylene carbonate, sulfone solvents such as sulfolane, and lactone solvents such as γ-butyrolactone, which may be used either singly or as a mixture of two or more of them. However, these examples are not limitative.

Meanwhile, as solvent of the electrolyte solution in a dye-sensitized solar cell, volatile organic solvents such as acetonitrile have been used. However, the dye-sensitized solar cell has had a problem that, when the electrolyte solution is exposed to the atmosphere due to breakage of the solar cell, transpiration of the electrolyte solution would occur, leading to a failure of the solar cell. In order to solve this problem, in recent years, difficulty volatile molten salts called ionic liquids have come to be used, instead of volatile organic solvents, as solvent of the electrolyte solution of the dye-sensitized solar cell (see, for example, Non-Patent Documents 3 and 4). As a result, the problem of volatilization of the electrolyte solution in dye-sensitized solar cells is being improved. However, ionic liquids are much higher in viscosity coefficient than the organic solvents which have been used; therefore, photoelectric conversion characteristics of the dye-sensitized solar cells using the ionic liquids are actually poorer than those of the conventional dye-sensitized solar cells. Accordingly, there is a need for a dye-sensitized solar cell in which volatilization of the electrolyte solution can be restrained and excellent photoelectric conversion characteristics can be obtained. In order to solve the problems, the present inventors made intensive and extensive studies. In the process of their studies, particularly in search for an improving measure for the problem of deterioration of photoelectric conversion characteristics in using an ionic liquid as solvent of the electrolyte solution, they made an attempt to dilute ionic liquids with organic solvents, while expecting that no improving effect would be obtainable by the dilution. The results were as expected. That is, when a solvent obtained by diluting an ionic liquid with a volatile organic solvent is used for the electrolyte solution, photoelectric conversion characteristics are enhanced due to lowering in the viscosity coefficient of the electrolyte solution, but there still remains the problem of volatilization of the organic solvent. However, in order to proceed with the verification, the present inventors made further attempts to dilute the inorganic liquids using various organic solvents. As a result, they found out that certain combinations of ionic liquid with organic solvent makes it possible to effectively restrain the volatilization of the electrolyte solution, without degrading the photoelectric conversion characteristics. This was a surprising result beyond expectation. Based on the unexpected finding, the present inventors advanced experimental and theoretical investigations. As a result, they reached a conclusion that it is effective to contain in the solvent of the electrolyte solution an ionic liquid having an electron-acceptive functional group and an organic solvent having an electron-donative functional group. In this case, in the solvent of the electrolyte solution, a hydrogen bond is formed between the electron-acceptive functional group of the ionic liquid and the electron-donative functional group of the organic solvent. Since the molecule of the ionic liquid and the molecule of the organic solvent are coupled together through the hydrogen bond, it is possible to restrain volatilization of the organic solvent and, hence, of the electrolyte solution, as compared with the case where the organic solvent is used alone. Further, since the solvent of the electrolyte solution contains the organic solvent in addition to the ionic liquid, the viscosity coefficient of the electrolyte solution can be lowered and deterioration of photoelectric conversion characteristics can be prevented, as compared with the case where only the ionic liquid is used as the solvent. Consequently, volatilization of the electrolyte solution can be restrained, and excellent photoelectric conversion characteristics can be obtained.

Here, the term “ionic liquid” includes not only salts which show liquid state at 100° C. (inclusive of salts which can be in liquid state at room temperature due to supercooling, notwithstanding their melting points or glass transition temperatures of not less than 100° C.) but also other salts which are brought into liquid state while forming one or more phases upon addition of a solvent thereto. The ionic liquid may basically be any ionic liquid that has an electron-acceptive functional group, and the organic solvent may fundamentally be any organic solvent that has an electron-donative functional group. The ionic liquid, typically, is that in which a cation has an electron-acceptive functional group. The ionic liquid, preferably, includes an organic cation which has an aromatic amine cation having a quaternary nitrogen atom and which has a hydrogen atom in an aromatic ring, and an anion (inclusive of not only organic anions but also inorganic anions such as AlCl₄⁻ and FeCl₄⁻) which has a van der Waals volume of not less than 76 Å³, the combination being non-limitative. The content of the ionic liquid in the solvent is selected, if necessary; preferably, the ionic liquid is contained in a proportion of not less than 15 wt % and less than 100 wt %, based on the solvent which includes the ionic liquid and the organic solvent. The electron-donative functional group of the organic solvent, preferably, is an ether group or an amino group, which is a non-limitative example.

As described above, the solvent of the electrolyte solution contains an ionic liquid having an electron-acceptive functional group and an organic solvent having an electron-donative functional group, and this produces the following effect. In the solvent of the electrolyte solution, a hydrogen bond is formed between the electron-acceptive functional group of the ionic liquid and the electron-donative functional group of the organic solvent. Since the molecule of the ionic liquid and the molecule of the organic solvent are coupled together through the hydrogen bond, it is possible to restrain volatilization of the organic solvent and, hence, of the electrolyte solution, as compared with the case where the organic solvent is used alone. Further, since the solvent of the electrolyte solution contains the organic solvent in addition to the ionic liquid, the viscosity coefficient of the electrolyte solution can be lowered and deterioration of photoelectric conversion characteristics can be prevented, as compared with the case where only the ionic liquid is used as the solvent. Accordingly, it is possible to realize a photoelectric conversion element in which volatilization of the electrolyte solution can be restrained and excellent photoelectric conversion characteristics can be obtained.

By the way, the conventional dye-sensitized solar cells are generally produced in the following manner. First, a porous electrode is formed on a transparent conductive substrate. Next, a counter electrode is prepared, and the porous electrode on the transparent conductive substrate and the counter electrode are disposed to face each other. Then, a sealing material is formed at the outer peripheral portions of the transparent conductive substrate and the counter electrode, to form a space in which an electrolyte layer is to be sealed. Subsequently, an electrolyte solution is poured through a liquid pouring hole preliminarily formed in the counter electrode, to form the electrolyte layer. Next, the portion of the electrolyte solution flowing over to the outside from the liquid pouring hole of the counter electrode is wiped away. Thereafter, a sealing plate is adhered to the upper surface of the counter electrode so as to close the liquid pouring hole. In this manner, the desired dye-sensitized solar cell is produced. However, the conventional dye-sensitized solar cell has had a problem that, when the dye-sensitized solar cell is broken for some reason, the electrolyte solution may leak to the exterior from the electrolyte layer sealed between the porous electrode and the counter electrode. The present inventors have conducted intensive studies in order to solve the problems. As a result, they have found that it is effective that a dye-sensitized solar cell, more generally, a photoelectric conversion element has a structure in which an electrolyte layer having a porous film containing an electrolyte solution is provided between a porous electrode and a counter electrode. Such a method for producing a photoelectric conversion element includes, for example, disposing a porous film on one of a porous electrode and a counter electrode, and disposing the other of the porous electrode and the counter electrode on the porous film. In the method for producing a photoelectric conversion element, the porous film at the time of being disposed on one of the porous electrode and the counter electrode may or may not contain an electrolyte solution. When a porous film containing an electrolyte solution is used, the porous film containing the electrolyte solution constitutes the electrolyte layer. When a porous film not containing any electrolyte solution is used, an electrolyte solution can be poured into the porous film in a later process. For example, an electrolyte solution can be poured into the porous film in a state in which the porous film is sandwiched between the porous electrode and the counter electrode. Typically, the porous film is disposed on the porous electrode, and thereafter the counter electrode is disposed on the porous film, but this is not limitative. The method for producing a photoelectric conversion element further includes, if necessary, compressing the porous film after the porous film containing the electrolyte solution is disposed on the porous electrode and before the counter electrode is disposed on the porous film; where the compression is typically carried out by pressing the porous film in a direction perpendicular to the film surface. This ensures that when the porous film is compressed and its volume is thereby reduced, the electrolyte solution contained in the voids of the porous film is pressed out, to permeate the porous electrode. Consequently, a state in which the electrolyte solution is present throughout the range from the porous film to the porous electrode can be easily realized. The porous film to be used to constitute the electrolyte layer may be one of various porous films, and its structure, material, and the like are selected according to the necessity. As the porous film, an insulating one is used. The insulating porous film may be formed of an insulating material, or may be one obtained, for example, by a method in which surfaces of voids of a porous film formed of a conductive material are converted into an insulating material or the surfaces of the voids are coated with an insulating film. The porous film may be formed from an organic material or an inorganic material. Preferably, one of various non-woven fabrics is used as the porous film. Examples of the material include organic polymer compounds such as polyolefins, polyesters, and cellulose, which are not limitative. The porosity of the porous film is selected according to the necessity. The porosity in the state of being provided between the porous electrode and the counter electrode (the actual porosity) is preferably 50% or more. From the viewpoint of securing a high photoelectric conversion efficiency, the actual porosity is preferably selected to be not less than 80% and less than 100%. The electrolyte solution contained in the porous film constituting the electrolyte layer is, from the viewpoint of preventing volatilization thereof, preferably a lowly volatile electrolyte solution, for example, an ionic liquid electrolyte solution in which an ionic liquid is used as a solvent. The ionic liquid to be used may be one of known ones, and is selected according to the necessity.

### Effects of the Invention

According to the present disclosure, the first additive is added to the electrolyte layer. Accordingly, for example, even if the durability test is performed in a dark place at 85° C., a great improvement in the maintenance rate of the photoelectric conversion efficiency can be achieved, and a great improvement in the durability can be achieved. Consequently, the use of the excellent photoelectric conversion element allows a high-performance electronic equipment and the like to be realized.

### BRIEF DESCRIPTION OF DRAWINGS

FIG. 1 is a sectional view showing a dye-sensitized photoelectric conversion element according to a first embodiment.

FIG. 2A is a sectional view showing a method for producing a dye-sensitized photoelectric conversion element according to a second embodiment. FIG. 2B is a sectional view showing the method for producing a dye-sensitized photoelectric conversion element according to the second embodiment. FIG. 2C is a sectional view showing the method for producing a dye-sensitized photoelectric conversion element according to the second embodiment.

FIG. 3 is a diagram showing the results of measurement of photoelectric conversion characteristics for dye-sensitized photoelectric conversion elements in Reference examples 1 to 5.

FIG. 4 is a diagram showing the results of measurement of photoelectric conversion characteristics for dye-sensitized photoelectric conversion elements in Reference examples 6 and 7.

FIG. 5 is a diagram showing the relationship between actual porosity of a porous film constituting an electrolyte layer and normalized photoelectric conversion efficiency, for the dye-sensitized photoelectric conversion elements in Reference examples 1 to 7.

FIG. 6 is a diagram showing the results of measurement of IPCE spectrum of the dye-sensitized photoelectric conversion element in Reference example 7.

FIG. 7A is a diagram showing the state of light transmitted through an electrolyte layer, where the light has failed to be absorbed by a photosensitizing dye in a conventional dye-sensitized photoelectric conversion element in which an electrolyte layer having only an electrolyte solution is used. FIG. 7B is a diagram showing the manner of scattering of light by an electrolyte layer in the dye-sensitized photoelectric conversion element according to the second embodiment.

FIG. 8A is a sectional view showing a method for producing a dye-sensitized photoelectric conversion element according to a third embodiment. FIG. 8B is a sectional view showing the method for producing a dye-sensitized photoelectric conversion element according to the third embodiment. FIG. 8C is a sectional view showing the method for producing a dye-sensitized photoelectric conversion element according to the third embodiment.

FIG. 9A is a sectional view showing the method for producing a dye-sensitized photoelectric conversion element according to the third embodiment. FIG. 9B is a sectional view showing the method for producing a dye-sensitized photoelectric conversion element according to the third embodiment.

FIG. 10 is a diagram showing the relationship between pKₐ of various additives and photoelectric conversion efficiency of dye-sensitized photoelectric conversion elements in which the additives are added to the electrolyte solution.

FIG. 11 is a diagram showing the relationship between pKₐ of various additives to be added to the electrolyte solution and internal resistance of the dye-sensitized photoelectric conversion elements in which the additives are added to the electrolyte solution.

FIG. 12 is a diagram showing dependence of the effect of an additive on the kind of solvent of the electrolyte solution.

FIG. 13 is a sectional view showing the structure of a metal/metal oxide particle constituting a porous electrode in a dye-sensitized photoelectric conversion element according to a fifth embodiment.

### MODE FOR CARRYING OUT THE INVENTION

Hereinafter, modes for carrying out the invention (hereinafter referred to as “embodiments”) will be described. The description will be made in the following order.

1. First embodiment (dye-sensitized photoelectric conversion element and method for producing the same)
2. Second embodiment (dye-sensitized photoelectric conversion element and method for producing the same)
3. Third embodiment (dye-sensitized photoelectric conversion element and method for producing the same)
4. Fourth embodiment (dye-sensitized photoelectric conversion element and method for producing the same)
5. Fifth embodiment (dye-sensitized photoelectric conversion element and method for producing the same)
6. Sixth embodiment (photoelectric conversion element and method for producing the same)

### 1. First Embodiment

### Dye-Sensitized Photoelectric Conversion Element

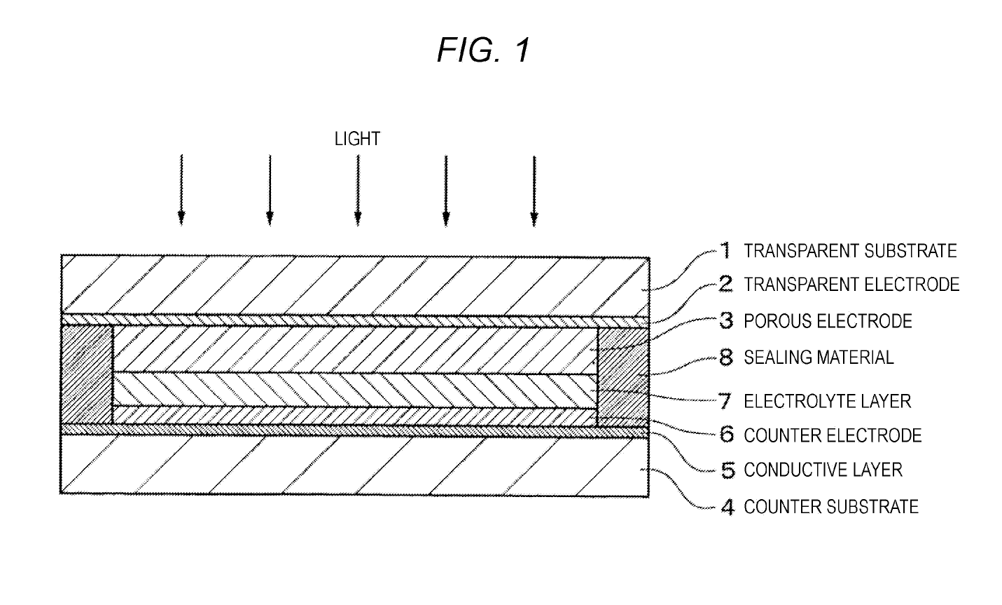

FIG. 1 is a major sectional view showing a dye-sensitized photoelectric conversion element according to a first embodiment.

As shown in FIG. 1, in the dye-sensitized photoelectric conversion element, a transparent electrode 2 is provided on one principal surface of a transparent substrate 1, and a porous electrode 3 having a predetermined planar shape which is smaller than the transparent electrode 2 is provided on the transparent electrode 2. One or more photosensitizing dyes (not shown) are bonded to the porous electrode 3. On the other hand, a conductive layer 5 is provided on one principal surface of a counter substrate 4, and a counter electrode 6 is provided on the conductive layer 5. The counter electrode 6 has the same planar shape as that of the porous electrode 3. An electrolyte layer 7 containing an electrolyte solution is provided between the porous electrode 3 on the transparent substrate 1 and the counter electrode 6 on the counter substrate 4. Additionally, outer peripheral portions of the transparent substrate 1 and the counter substrate 4 are sealed with a sealing material 8. The sealing material 8 is in contact with the transparent electrode 2 and the conductive layer 5. The transparent electrode 2 may be formed in the same planar shape as the porous electrode 3 so that the sealing material 8 makes contact with the transparent substrate 1, or the counter electrode 6 may be formed over the whole area of the conductive layer 5 so that the sealing material 8 makes contact with the conductive layer 5.

As the porous electrode 3, typically, a porous semiconductor layer obtained by sintering semiconductor particles is used. A photosensitizing dye is adsorbed on the surfaces of the semiconductor particles. As the material for the semiconductor particles, elemental semiconductors represented by silicon, compound semiconductors, and semiconductors having a perovskite structure and the like can be used. These semiconductors are preferably n-type semiconductors in which conduction band electrons become carriers under excitation with light, producing an anode current. Specifically, semiconductors such as titanium oxide (TiO₂), zinc oxide (ZnO), tungsten oxide (WO₃), niobium oxide (Nb₂O₅), strontium titanate (SrTiO₃), and tin oxide (SnO₂) are used. Among these semiconductors, TiO₂, particularly, anatase-type TiO₂ is preferably used. However, these semiconductors are not limitative, and a mixture or composite material of two or more of the semiconductors can be used, if necessary. Further, the form of the semiconductor particles may be any of granular form, tubular form, and rod-like form.

While the particle diameter of the semiconductor particles is not particularly limited, it is preferably 1 to 200 nm, particularly preferably 5 to 100 nm, in terms of average particle diameter of primary particles. The semiconductor particles are mixed with particles greater in size than the semiconductor particles, and the incident light is scattered by the semiconductor particles, thereby enhancing quantum yield. In this case, the average size of the semiconductor particles mixed is preferably 20 to 500 nm, which is not limitative.

In order to enable as large an amount as possible of a photosensitizing dye to be bonded to the porous electrode 3, the porous electrode 3 preferably has a large actual surface area which includes the particulate surfaces facing the pores in the inside of the porous semiconductor layer having the semiconductor particles. Thus, the actual surface area in the state in which the porous electrode 3 is formed on the transparent electrode 2 is preferably not less than ten times, more preferably not less than 100 times, the outside surface area (projection area) of the porous electrode 3. The ratio does not have a particular upper limit, but, ordinarily, the ratio is about 1000 times.

In general, as the thickness of the porous electrode 3 increases and the number of the semiconductor particles contained per unit projection area increases, the actual surface area increases and the amount of the photosensitizing dye which can be held in unit projection area increases, resulting in an increase in light absorptivity. On the other hand, as the thickness of the porous electrode 3 increases, the distance by which the electrons transferred from the photosensitizing dye to the porous electrode 3 diffuse until they reach the transparent electrode 2 increases, so that the loss of electrons due to charge coupling in the porous electrode 3 is also increased. Therefore, there is a preferable thickness for the porous electrode 3. The thickness is generally 0.1 to 100 μm, more preferably 1 to 50 μm, and particularly preferably 3 to 30 μm.

At least one of the various first additives is added to an electrolyte solution constituting the electrolyte layer 7. The composition of the first additive is selected according to the necessity. It is, for example, 0.01 to 1 M, typically 0.05 to 0.5 M.

The electrolyte solution constituting the electrolyte layer 7 is, for example, a solution containing an oxidation-reduction system (redox pair). The oxidation-reduction system is not particularly limited insofar as it includes substances which have appropriate oxidation-reduction potentials. Specifically, as the oxidation-reduction system, for example, a combination of iodine (I₂) with an iodide salt of a metal or organic substance, or a combination of bromine (Br₂) with a bromide salt of a metal or organic substance is used. Examples of the cation constituting the metal salt include lithium (Li⁺), sodium (Na⁺), potassium (K⁺), cesium (Cs⁺), magnesium (Mg²⁺), and calcium (Ca²⁺). Further, examples of the cation constituting the organic salt include quaternary ammonium ions such as tetraalkylammonium ions, pyridinium ions, and imidazolium ions. These can be used either singly or as a mixture of two or more of them.

Other examples as the electrolyte solution constituting the electrolyte layer 7 include: combinations of an oxidized product and a reduced product of an organometal complex having a transition metal such as cobalt, iron, copper, nickel, and platinum; sulfur compounds such as combinations of sodium polysulfide or an alkyl thiol with an alkyl disulfide; viologen dyes; and a combination of hydroquinone with quinone.

Among the above electrolytes, those electrolytes which are obtained by combining iodine (I₂) with lithium iodide (LiI), sodium iodide (NaI), or a quaternary ammonium compound such as imidazoium iodide are particularly preferable as the electrolyte in the electrolyte solution constituting the electrolyte layer 7. The concentration of the electrolyte salt based on the amount of solvent is preferably 0.05 to 10 M, more preferably 0.2 to 3 M. The concentration of iodine (I₂) or bromine (Br₂) is preferably 0.0005 to 1 M, more preferably 0.001 to 0.5 M. Further, various additives such as 4-tert-butylpyridine and benzimidazoliums can be added, for the purpose of enhancing open circuit voltage and short-circuit current.

Examples of the solvent which can be used as the solvent constituting the electrolyte solution, in general, include water, alcohols, ethers, esters, carbonic acid esters, lactones, carboxylic acid esters, phosphoric acid triesters, heterocyclic compounds, nitriles, ketones, amides, nitromethane, halogenated hydrocarbons, dimethyl sulfoxide, sulfolane, N-methylpyrrolidone, 1,3-dimethylimidazolidinone, 3-methyloxazolidinone, and hydrocarbons.

As the solvent constituting the electrolyte solution, an ionic liquid can also be used, whereby the problem of volatilization of the electrolyte solution can be improved. As the ionic liquid, those which have been known can be used, though they are selected according to the necessity. Specific examples thereof are as follows.
EMImTCB: (1-ethyl-3-methylimidazolium tetracyanoborate)
EMImTFSI: (1-ethyl-3-methylimidazolium bis(trifluoromethanesulfonyl)imide)
EMImFAP: (1-ethyl-3-methylimidazolium tris(pentafluoroethyl)trifluorophosphate)
EMImBF₄: (1-ethyl-3-methylimidazolium tetrafluoroborate)
EMImOTf (1-ethyl-3-methylimidazolium trifluorosulfonate))
P₂₂₂MOMTFSI (triethyl(methoxymethyl)phosphonium bis(trifluoromethylsulfonyl)imide).

The transparent substrate 1 is not particularly limited insofar as it has a shape and a material such as to permit easy transmission of light therethrough. While various substrate materials can be used, it is particularly preferable to use a substrate material which has high transmittance with respect to visible light. Further, a material which has high barrier performance for blocking moisture and gases tending to enter into the dye-sensitized photoelectric conversion element from the outside and which is excellent in solvent resistance and weatherability is preferable. Specific examples of the material to be used as the transparent substrate 1 include transparent inorganic materials such as quartz, glass, and transparent plastics such as polyethylene terephthalate, polyethylene naphthalate, polycarbonate, polystyrene, polyethylene, polypropylene, polyphenylene sulfide, polyvinylidene fluoride, acetyl cellulose, brominated phenoxy, aramids, polyimides, polystyrenes, polyarylates, polysulfones, and polyolefins. The thickness of the transparent substrate 1 is not particularly limited, and it can be appropriately selected taking into account light transmittance and performance as barrier between the inside and the outside of the photoelectric conversion element.

The transparent electrode 2 provided on the transparent substrate 1 is more preferable as its sheet resistance is lower. Specifically, the sheet resistance is preferably 500Ω/□ or less, more preferably 100Ω/□ or less. As the material for forming the transparent electrode 2, known materials can be used, though they are selected according to the necessity. Specific examples of the material for forming the transparent electrode 2 include indium-tin composite oxide (ITO), fluorine-doped tin(IV) oxide SnO₂ (FTO), tin(IV) oxide SnO₂, zinc(II) oxide ZnO, and indium-zinc composite oxide (IZO). However, the material for forming the transparent electrode 2 is not limited to these examples and two or more of them can also be used in combination.

The photosensitizing dye to be bonded to the porous electrode 3 is not particularly limited insofar as it exhibits a photosensitizing action. While organometal complexes, organic dyes, metal-semiconductor nanoparticles and the like can be used, those which have an acid functional group suitable for adsorption on the surface of the porous electrode 3 are preferred. Among the photosensitizing dyes, those which have a carboxyl group, a phosphate group or the like are preferable, and those which have a carboxyl group are particularly preferable. Specific examples of the photosensitizing dye include: xanthene dyes such as Rhodamine B, Rose Bengale, eosine, and erythrosine; cyanine dyes such as merocyanine, quinocyanine, and cryptocyanine; basic dyes such as phenosafranine, Cabri blue, thiocine, and Methylene Blue; and porphyrin compounds such as chlorophyll, zinc porphyrin, and magnesium porphyrin. Other examples include azo dyes, phthalocyanine compounds, cumarin compounds, pyridine complex compounds, anthraquinone dyes, polycyclic quinone dyes, traphenylmethane dyes, indoline dyes, perylene dyes, n-conjugate polymers such as polythiophene and dimers to 20-mers of their monomers, and quantum dots of CdS, CdSe. Among them, those in which a ligand contains a pyridine ring or an imidazolium ring and which are a complex of at least one metal selected from the group consisting of Ru, Os, Ir, Pt, Co, Fe, and Cu, are preferred because they are high in quantum yield. Particularly, dye molecules having cis-bis(isothiocyanato)-N,N-bis(2,2′-dipyridyl-4,4′-dicarboxylate)-ruthen-ium(II) or tris(isothiocyanato)-ruthenium(II)-2,2′:6′,2″-terpyridine-4,4′-,4″-tricarboxylic acid as a fundamental skeleton thereof are preferred because of wide absorption wavelength range. However, the photosensitizing dye is not limited to these examples. While one of the photosensitizing dyes is typically used, a mixture of two or more of the photosensitizing dyes may also be used. In the case where a mixture of two or more photosensitizing dyes is used, the photosensitizing dyes preferably include an inorganic complex dye having a property for causing MLCT (Metal to Ligand Charge Transfer) and held on the porous electrode 3, and an organic molecular dye having a property for intramolecular CT (Charge Transfer) and held on the porous electrode 3. In this case, the inorganic complex dye and the organic molecule dye are adsorbed on the porous electrode 3 in different conformations. The inorganic complex dye, preferably, has a carboxyl group or a phosphono group as the functional group for bonding to the porous electrode 3. On the other hand, the organic molecular dye preferably has, on the same carbon atom, a carboxyl group or a phosphono group and a cyano group, an amino group, a thiol group or a thione group as the functional groups for bonding to the porous electrode 3. The inorganic complex dye is, for example, a polypyridine complex, whereas the organic molecular dye is, for example, an aromatic polycyclic conjugated molecule which has both an electron-donative group and an electron-acceptive group and has a property for intramolecular CT.

The method for adsorbing the photosensitizing dye onto the porous electrode 3 is not particularly limited. For example, the photosensitizing dye as described above may be dissolved in a solvent such as alcohols, nitriles, nitromethane, halogenated hydrocarbon, ethers, dimethyl sulfoxide, amides, N-methylpyrrolidone, 1,3-dimethylimidazolidinone, 3-methyloxazolidinone, esters, carbonic acid esters, ketones, hydrocarbon or water, and then the porous electrode 3 may be immersed in the solution containing the photosensitizing dye or the solution may be applied to the porous electrode 3. Further, for the purpose of suppressing association between molecules of the photosensitizing dye, deoxycholic acid or the like may be added. A UV absorber may be used together, if necessary.

After the photosensitizing dye is adsorbed on the porous electrode 3, the surface of the porous electrode 3 may be treated with amines, for the purpose of accelerating the removal of the photosensitizing dye adsorbed in excess. Examples of the amines include 4-tert-butylpyridine and polyvinylpyridine, which may be used as they are in the case of liquid samples or used in the state of being dissolved in an organic solvent.

As the material for the counter electrode 6, any conductive material can be used. In addition, an insulating material provided with a conductive layer on its side facing the electrolyte layer 7 can also be used. A material which is electrochemically stable is desired as the material for the counter electrode 6. Specifically, desirable examples thereof include platinum, gold, carbon, and conductive polymers.

Further, for enhancing the catalytic action to the reduction reaction on the counter electrode 6, the surface of the counter electrode 6 which is in contact with the electrolyte layer 7 is preferably formed with a microstructure to increase the actual surface area. For example, the surface of the counter electrode 6 is preferably formed to be in the state of platinum black in the case where the electrode material is platinum, and is preferably formed to be in the state of porous carbon in the case where the electrode material is carbon. Platinum black can be formed by subjecting platinum to an anodic oxidation treatment or a chloroplatinic acid treatment or the like, whereas the porous carbon can be formed by sintering of carbon particles or calcination of an organic polymer or the like.

The counter electrode 6 is formed on the conductive layer 5 formed on one principal surface of the counter substrate 4, but this configuration is not limitative. As the material for the counter substrate 4, there can be used opaque glasses, plastics, ceramics, metals and the like, and there can also be used transparent materials, for example, transparent glasses and plastics. As the conductive layer 5, layers which are the same as or similar to those for the transparent electrode 2 can be used. Further, layers formed of opaque conductive materials can also be used.

As the material for the sealing material 8, it is preferable to use a material which has light fastness, insulating properties, moisture barrier properties and the like. Specific examples of the material for the sealing material 8 include epoxy resin, UV-curing resins, acrylic resin, polyisobutylene resin, EVA (ethylene vinyl acetate), ionomer resins, ceramics, and various fusible films.

Further, when an electrolyte solution is poured, it is necessary to provide an inlet, and a place of the inlet is not particularly limited except for the porous electrode 3, and a portion on the counter electrode 6 facing the porous electrode 3. Further, a method for pouring the electrolyte solution is not particularly limited, and it is preferred to use a method in which the outer peripheral portion is preliminarily sealed, and the solution is poured into a photoelectric conversion element in which the inlet for the solution is opened under reduced pressure. In this case, several droplets of the solution are dropped to the inlet to be poured by the capillary phenomenon, which is simple. Further, the process of pouring the solution can also be operated either under the reduced pressure or under the heating according to the necessity. After the solution has been perfectly poured, the solution remaining in the inlet is removed, and the inlet is sealed. There is not also particularly a limit to the sealing method. If necessary, a glass plate or a plastic substrate is attached to the inlet using a sealing agent, to allow the inlet to be sealed. In addition to this method, like an One Drop Filling (ODF) process for a liquid crystal panel, the electrolyte solution is dropped onto the substrate, followed by attachment under the reduced pressure to allow the inlet to be sealed. After the completion of sealing, for the purpose of sufficiently impregnating the porous electrode 3 with the electrolyte solution, an operation for heating or application of pressure can also be performed, if necessary.

### [Method for Producing Dye-Sensitized Photoelectric Conversion Element]

Subsequently, a method for producing the dye-sensitized photoelectric conversion element will be described.

First, a transparent conductive layer is formed on one principal surface of a transparent substrate 1 by spattering or the like, to form a transparent electrode 2.

Next, a porous electrode 3 is formed on the transparent electrode 2 of the transparent substrate 1. Although the method for forming the porous electrode 3 is not particularly limited, a wet film forming method is preferably used, taking physical properties, convenience, production cost and the like into consideration. The wet film forming method is preferably carried out by uniformly dispersing a powder or sol of semiconductor particles in a solvent such as water, to prepare a pasty dispersion, and applying or printing the dispersion onto the transparent electrode 2 on the transparent substrate 1. The dispersion applying method or printing method is not particularly limited, and known methods can be used. Specific examples of the application method which can be used include dipping method, spraying method, wire bar method, spin coating method, roller coating method, blade coating method, and gravure coating method. Further, examples of the printing method which can be used include relief printing method, offset printing method, gravure printing method, intaglio printing method, rubber plate printing method, and screen printing method.

In the case where anatase type TiO₂ is used as the material for the semiconductor particles, the anatase type TiO₂ may be a commercial product which is in a powdery, sol or slurry state, or it may be prepared to have a predetermined particle diameter by a known method, such as hydrolysis of titanium oxide alkoxide. In using a commercial powdery anatase type TiO₂, it is preferable to avoid secondary agglomeration of the particles; therefore, it is preferable to pulverize the particles by using a mortar, a ball mill or the like at the time of preparing the pasty dispersion. At this time, acetylacetone, hydrochloric acid, nitric acid, a surfactant, a chelating agent or the like can be added to the pasty dispersion, in order to prevent re-aggregation of the particles which have been prevented from secondary agglomeration. Further, polymers such as polyethylene oxide and polyvinyl alcohol or thickeners such as a cellulosic thickener can be added to the pasty dispersion, in order to increase the viscosity of the pasty dispersion.

After the semiconductor particles are applied or printed onto the transparent electrode 2, calcination is preferably conducted in order to electrically connect the semiconductor particles to one another, to enhance the mechanical strength of the porous electrode 3, and to enhance adhesion of the porous electrode 3 to the transparent electrode 2. The range of calcination temperature is not particularly limited. If the calcination temperature is too high, the electric resistance of the transparent electrode 2 would be raised, and, further, the transparent electrode 2 might be melted. Normally, therefore, the sintering temperature is preferably 40 to 700° C., more preferably 40 to 650° C. Further, calcination time also is not particularly limited; normally, however, it is about 10 minutes to about 10 hours.

After the calcinations, a dipping treatment using, for example, an aqueous solution of titanium tetrachloride or a sol of titanium oxide ultrafine particles having a diameter of 10 nm or less may be performed, for the purpose of increasing the surface areas of the semiconductor particles or promoting necking among the semiconductor particles. In the case where a plastic substrate is used as the transparent substrate 1 for supporting the transparent electrode 2, a process may be carried out in which the porous electrode 3 is formed on the transparent electrode 2 by using a pasty dispersion containing a binder and the porous electrode 3 is pressure bonded to the transparent electrode 2 by a hot press.

Next, the transparent substrate 1 with the porous electrode 3 formed thereon is immersed in a solution prepared by dissolving a photosensitizing dye in a predetermined solvent, thereby bonding the photosensitizing dye to the porous electrode 3.

On the other hand, a conductive layer 5 is formed on the whole area of a surface of a counter electrode 4 by sputtering, for example, and thereafter a counter electrode 6 having a predetermined planar shape is formed on the conductive layer 5. The counter electrode 6 can be formed, for example, by a method in which a film to be a material of the counter electrode 6 is formed over the whole surface of the conductive layer 5 by, for example, sputtering or the like, and thereafter the film is patterned by etching.

Subsequently, the transparent substrate 1 and the counter substrate 4 are arranged to face each other at a predetermined interval between the porous electrode 3 and the counter electrode 6 (for example, 1 to 100 μm, preferably 1 to 50 μm). Then, a sealing material 8 is formed at outer peripheral portions of the transparent substrate 1 and the counter substrate 4, to form a space in which the electrolyte layer 7 is to be sealed. For example, an electrolyte solution to which the first additive has been added is poured into the space through a liquid pouring port (not shown) preliminarily formed in the transparent substrate 1, to form the electrolyte layer 7. Thereafter, this liquid pouring port is closed.

In this manner, the desired dye-sensitized photoelectric conversion element is produced.

### [Operation of Dye-Sensitized Photoelectric Conversion Element]

Subsequently, operation of the dye-sensitized photoelectric conversion element will be described.

The dye-sensitized photoelectric conversion element, upon incidence of light thereon, operates as a cell with the counter electrode 6 as a positive electrode and with the transparent electrode 2 as a negative electrode. The principle of the operation is as follows. Incidentally, here, it is assumed that FTO is used as material for the transparent electrode 2, TiO₂ is used as material for the porous electrode 3, and oxidation-reduction species of I⁻/I₃⁻ are used as the redox pair. Further, it is assumed that one kind of photosensitizing dye is bonded to the porous electrode 3.

When photons transmitted through the transparent substrate 1 and the transparent electrode 2 and incident on the porous electrode 3 are absorbed by the photosensizing dye bonded to the porous electrode 3, electrons in the photosensitizing dye are excited from the ground state (HOMO) to the excited state (LUMO). The electrons thus excited are drawn through the electrical bonding between the photosensitizing dye and the porous electrode 3 into the conduction band of TiO₂ constituting the porous electrode 3, and pass through the porous electrode 3, to reach the transparent electrode 2.

On the other hand, the photosensitizing dye having lost the electrons accepts electrons from a reducing agent, for example, I⁻ present in the electrolyte layer 7 through the following reaction, and produces an oxidizing agent, for example, I₃ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above reaction, and is thereby reduced to the original reducing agent.

I₃⁻→I₂+I⁻

I₂+2e⁻→2I⁻

The electrons sent out from the transparent electrode 2 to an external circuit perform an electrical work in the external circuit, and thereafter return to the counter electrode 6. In this manner, optical energy is converted into electrical energy, without leaving any change in either of the photosensitizing dye and the electrolyte layer 7.

### Example 1

A dye-sensitized photoelectric conversion element was produced in the following manner.

A pasty dispersion of TiO₂ as a raw material in forming a porous electrode 3 was prepared with reference to “Shikiso Zokan Taiyo Denchi No Saishin Gijutsu (The Latest Technologies of Dye-Sensitized Solar Cells)” (supervised by Hironori Arakawa, 2001, CMC Publishing Co., Ltd.). That is, first, 125 ml of titanium isopropoxide was gradually added dropwise to 750 ml of a 0.1 M aqueous solution of nitric acid while stirring at room temperature. After the dropwise addition, the mixture was transferred into a thermostat at 80° C., and stirring was continued for 8 hours, to obtain a milky white semi-transparent sol solution. The sol solution was cooled to room temperature, and was filtered through a glass filter. Thereafter, a solvent was added thereto until the volume of the solution became 700 ml. The obtained sol solution was transferred into an autoclave, a hydrothermal reaction was performed at 220° C. for 12 hours, and then an ultrasonic treatment as a dispersing treatment was performed for 1 hour. Next, the solution was concentrated at 40° C. using an evaporator to adjust the TiO₂ content to 20 wt %. The thus concentrated sol solution was admixed with polyethylene glycol (molecular weight: 500,000) in an amount corresponding to 20% of the mass of TiO₂ and anatase-type TiO₂ with a particle diameter of 200 nm in an amount corresponding to 30% of the mass of TiO₂, and the resulting admixture was uniformly blended by a stirrer-deaerator, to obtain a pasty dispersion of TiO₂ having an increased viscosity.

The above pasty dispersion of TiO₂ was applied onto an FTO layer, serving as a transparent electrode 2, by blade coating method, to form a particle layer measuring 5 mm×5 mm and 200 μm in thickness. Thereafter, the assembly was held at 500° C. for 30 minutes, to sinter the TiO₂ particles on the FTO layer. A 0.1 M aqueous solution of titanium(IV) chloride TiCl₄ was dropped onto the sintered TiO₂ film, then the assembly was held at room temperature for 15 hours, and then washed, and was subjected again to calcinations at 500° C. for 30 minutes. Thereafter, the sintered TiO₂ body was irradiated with UV light for 30 minutes using a UV irradiation apparatus, whereby a treatment for removing impurities such as organic matter contained in the sintered TiO₂ body through oxidative decomposition by the photocatalytic action of TiO₂ was conducted and a treatment for enhancing an activity of the sintered TiO₂ was performed to obtain a porous electrode 3.

In 50 ml of a mixed solvent prepared by mixing acetonitrile and tert-butanol in a volume ratio of 1:1, 23.8 mg of sufficiently purified 2907 as photosensitizing dye was dissolved, to prepare a photosensitizing dye solution.

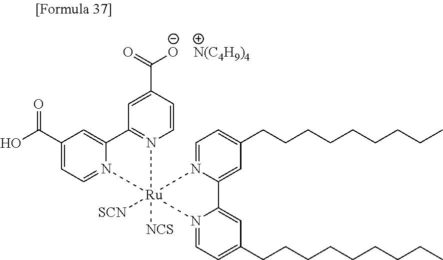

Next, in the photosensitizing dye solution, the porous electrode 3 was immersed at room temperature for 24 hours, to hold the photosensitizing dye on the surfaces of TiO₂ particles. Subsequently, the porous electrode 3 was cleaned sequentially with an acetonitrile solution of 4-tert-butylpyridine and with acetonitrile, thereafter the solvents were evaporated off in a dark place, and the porous electrode 3 was dried.

A 50 nm-thick chromium layer and a 100 nm-thick platinum layer were sequentially stacked on an FTO layer (with a liquid pouring port having a diameter of 0.5 mm previously formed thereon) by a sputtering method. Then, the platinum layer was spray-coated with an isopropyl alcohol (2-propanol) solution of chloroplatinic acid, followed by heating at 385° C. for 15 minutes, to obtain the counter electrode 6.

Subsequently, the transparent substrate 1 and the counter substrate 4 were disposed to face the porous electrode 3 and the counter electrodes 6. The outer periphery was sealed with a 30 μm-thick ionomer resin film and an acrylic UV-curing resin.

On the other hand, 0.10 g of iodine I₂, 0.3 M of N-butylbenzimidazole (NBB) as a second additive, and 0.1 M of GuOTf as a first additive were dissolved in 1.0 M of 1-propyl-3-methylimidazolium iodide (MPImI)/EMImTCB used as solvent, to prepare an electrolyte solution.

The electrolyte solution was poured from the liquid pouring port of the dye-sensitized photoelectric conversion element preliminarily prepared, using a liquid-sending pump, followed by compression to remove the air bubbles in the element. In this manner, the electrolyte layer 7 is formed. Subsequently, the liquid pouring port is sealed with an ionomer resin film, an acrylic resin, and a glass substrate to complete the dye-sensitized photoelectric conversion element.

### Example 2

A dye-sensitized photoelectric conversion element was produced in the same manner as in Example 1, except that EMImSCN was used as a first additive to be added to an electrolyte solution.

### Example 3

A dye-sensitized photoelectric conversion element was produced in the same manner as in Example 1, except that EMImOTf was used as a first additive to be added to an electrolyte solution.

### Example 4

A dye-sensitized photoelectric conversion element was produced in the same manner as in Example 1, except that EMImTFSI was used as a first additive to be added to an electrolyte solution.

### Example 5

A dye-sensitized photoelectric conversion element was produced in the same manner as in Example 1, except that EMImTfAc was used as a first additive to be added to an electrolyte solution.

### Example 6

A dye-sensitized photoelectric conversion element was produced in the same manner as in Example 1, except that EMImDINHOP was used as a first additive to be added to an electrolyte solution.

### Example 7

A dye-sensitized photoelectric conversion element was produced in the same manner as in Example 1, except that EMImMeSO₃ was used as a first additive to be added to an electrolyte solution.

### Example 8

As a photosensitizing dye, 2991 represented by the following structural formula was used.

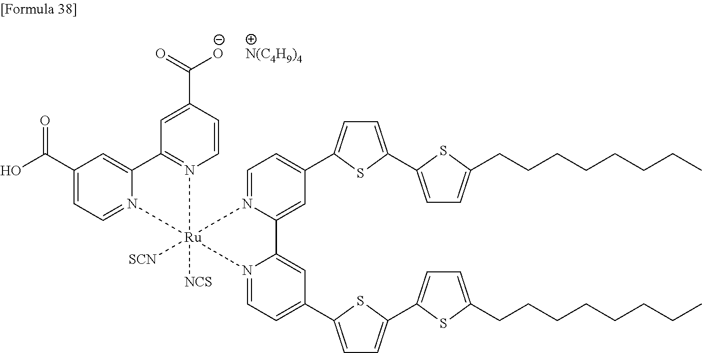

In 50 ml of a mixed solvent prepared by mixing acetonitrile and tert-butanol in a volume ratio of 1:1, 23.8 mg of sufficiently purified 2991 was dissolved, to prepare a photosensitizing dye solution. A dye-sensitized photoelectric conversion element was produced in the same manner as in Example 1, except that EMImSCN was used as a first additive to be added to an electrolyte solution.

### Example 9

A dye-sensitized photoelectric conversion element was produced in the same manner as in Example 8, except that EMImDCA was used as a first additive to be added to an electrolyte solution.

### Example 10

A dye-sensitized photoelectric conversion element was produced in the same manner as in Example 8, except that EMImBF₄ was used as a first additive to be added to an electrolyte solution.

### Example 11

A dye-sensitized photoelectric conversion element was produced in the same manner as in Example 8, except that EMImPF₆ was used as a first additive to be added to an electrolyte solution.

### Example 12

A dye-sensitized photoelectric conversion element was produced in the same manner as in Example 8, except that EMImFAP was used as a first additive to be added to an electrolyte solution.

### Example 13

A dye-sensitized photoelectric conversion element was produced in the same manner as in Example 8, except that EMImTFSI was used as a first additive to be added to an electrolyte solution.

### Example 14

A dye-sensitized photoelectric conversion element was produced in the same manner as in Example 8, except that EMImOTf was used as a first additive to be added to an electrolyte solution.

### Example 15

A dye-sensitized photoelectric conversion element was produced in the same manner as in Example 8, except that EMImTfAc was used as a first additive to be added to an electrolyte solution.

### Example 16

A dye-sensitized photoelectric conversion element was produced in the same manner as in Example 8, except that EMImMeSO₃ was used as a first additive to be added to an electrolyte solution.

### Example 17

A dye-sensitized photoelectric conversion element was produced in the same manner as in Example 8, except that EMImEt₂PO₄ was used as a first additive to be added to an electrolyte solution.

### Example 18

A dye-sensitized photoelectric conversion element was produced in the same manner as in Example 8, except that EMImCB₁₁H₁₂ was used as a first additive to be added to an electrolyte solution.

### Comparative Example 1

A dye-sensitized photoelectric conversion element was produced in the same manner as in Example 1, except that GuSCN was used as a first additive to be added to an electrolyte solution.

### Comparative Example 2

A dye-sensitized photoelectric conversion element was produced in the same manner as in Example 8, except that GuSCN was used as a first additive to be added to an electrolyte solution.

A durability test was performed on the dye-sensitized photoelectric conversion elements in Examples 1 to 18 and Comparative examples 1 and 2. The durability test was carried out in a dark place where the dye-sensitized photoelectric conversion element was held at 85° C. and temporal changes in the photoelectric conversion efficiency were measured. When the initial photoelectric conversion efficiency of each of the dye-sensitized photoelectric conversion elements in Examples 1 to 7 and Comparative example 1 was 100(%), the measurement results of the maintenance rate (%) of the photoelectric conversion efficiency after the lapse of 150 hours or 1000 hours are shown in Table 1. Table 1 shows the normalized photoelectric conversion efficiency, obtained by normalizing the photoelectric conversion efficiency of each of the dye-sensitized photoelectric conversion elements of Examples 1 to 7 after the lapse of 150 hours by the photoelectric conversion efficiency of the dye-sensitized photoelectric conversion element of Comparative example 1 after the lapse of 150 hours (the photoelectric conversion efficiency of the dye-sensitized photoelectric conversion element of Comparative example 1 after the lapse of 150 hours is 100). When the initial photoelectric conversion efficiency of each of the dye-sensitized photoelectric conversion elements in Examples 8 to 18 and Comparative example 2 was 100(%), the measurement results of the maintenance rate (%) of the photoelectric conversion efficiency after the lapse of 150 hours are shown in Table 2. Table 2 shows the normalized photoelectric conversion efficiency, obtained by normalizing the photoelectric conversion efficiency of each of the dye-sensitized photoelectric conversion elements of Examples 8 to 18 after the lapse of 150 hours by the photoelectric conversion efficiency of the dye-sensitized photoelectric conversion element of Comparative example 2 after the lapse of 150 hours (the photoelectric conversion efficiency of the dye-sensitized photoelectric conversion element of Comparative example 2 after the lapse of 150 hours is 100).

TABLE 1

| | | | | | 85° C., 150 h | 85° C., 1000 h | GuSCN- |
|---|---|---|---|---|---|---|---|
| | | | | δ2H | Maintenance | Maintenance | normalized |
| | Dye | Cation | Anion | [ppm] | rate [%] | rate [%] | 150 h |
| Example 1 | Z907 | [Gu] | [OTf] | | 99.2 | 91.5 | 106.5 |
| Example 2 | Z907 | [EMIm] | SCN | 8.498 | 94.4 | 89.0 | 101.3 |
| Example 3 | Z907 | [EMIm] | [OTf] | 8.201 | 100.2 | 93.4 | 107.5 |
| Example 4 | Z907 | [EMIm] | [TFSI] | 7.934 | 99.5 | 92.5 | 106.8 |
| Example 5 | Z907 | [EMIm] | [TfAc] | 9.135 | 99.6 | 95.5 | 106.9 |
| Example 6 | Z907 | [EMIm] | [DINHOP] | | 102.0 | 83.9 | 109.4 |
| Example 7 | Z907 | [EMIm] | [MeSO₃] | 8.836 | 97.9 | 91.4 | 105.1 |
| Comparative | Z907 | [Gu] | SCN | | 93.2 | 85.2 | 100.0 |
| example 1 | | | | | | | |

TABLE 2

| | | | | | 85° C., 150 h | GuSCN- |
|---|---|---|---|---|---|---|
| | | | | δ2H | Maintenance | normalized |
| | Dye | Cation | Anion | [ppm] | rate [%] | 150 h |
| Example 8 | Z991 | [EMIm] | SCN | 8.498 | 82.8 | 101.1 |
| Example 9 | Z991 | [EMIm] | [DCA] | 8.545 | 89.5 | 109.2 |
| Example 10 | Z991 | [EMIm] | BF₄ | | 90.3 | 110.3 |
| Example 11 | Z991 | [EMIm] | PF₆ | | 93.7 | 114.3 |
| Example 12 | Z991 | [EMIm] | [FAP] | | 93.7 | 114.4 |
| Example 13 | Z991 | [EMIm] | [TFSI] | 7.934 | 95.0 | 116.0 |
| Example 14 | Z991 | [EMIm] | [OTf] | 8.201 | 92.3 | 112.6 |
| Example 15 | Z991 | [EMIm] | [TfAc] | 9.135 | 94.3 | 115.1 |
| Example 16 | Z991 | [EMIm] | [MeSO₃] | | 90.7 | 110.7 |
| Example 17 | Z991 | [EMIm] | [(EtO)₂PO₄] | | 91.1 | 111.2 |
| Example 18 | Z991 | [EMIm] | CB₁₁H₁₂ | | 93.6 | 114.2 |
| Comparative | Z991 | [Gu] | SCN | | 81.9 | 100.0 |
| example 2 | | | | | | |

In Table 1, the maintenance rates of the photoelectric conversion efficiencies of the dye-sensitized photoelectric conversion elements in Examples 1 to 7 are higher than that of the photoelectric conversion efficiency of the dye-sensitized photoelectric conversion element in Comparative example 1. Further, in Table 2, the maintenance rates of the photoelectric conversion efficiencies of the dye-sensitized photoelectric conversion elements in Examples 8 to 18 are higher than that of the photoelectric conversion efficiency of the dye-sensitized photoelectric conversion element in Comparative example 2. From these results, it is found that when GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄ or EMImCB₁₁H₁₂ is added to the electrolyte solution as the second additive, it is possible to achieve the improvement in the maintenance rate of the photoelectric conversion efficiency.

As described above, according to the first embodiment, the above first additive is added to the electrolyte solution constituting the electrolyte layer 7 of the dye-sensitized photoelectric conversion element. Accordingly, the improvement in the maintenance rate of the photoelectric conversion efficiency can be achieved, as compared with the conventional dye-sensitized photoelectric conversion element using GuSCN as an additive for the electrolyte solution. Thus, an improvement in durability of the dye-sensitized photoelectric conversion element can be achieved. Consequently, the use of the excellent dye-sensitized photoelectric conversion element allows a high-performance electronic equipment and the like to be realized.

### 2. Second Embodiment

### Dye-Sensitized Photoelectric Conversion Element

A dye-sensitized photoelectric conversion element according to a second embodiment differs from the dye-sensitized photoelectric conversion element according to the first embodiment in that an electrolyte layer 7 has a porous film containing or impregnated with an electrolyte solution.

As the porous film constituting the electrolyte layer 7, for example, various non-woven fabrics having organic polymers may be used. Table 3 show specific examples of the non-woven fabric which can be used as the porous film. However, these are not limitative.

TABLE 3

| | Material for | | Film | Actual |
|---|---|---|---|---|
| | non-woven | Porosity | thickness | porosity |
| | fabrics | (%) | (μm) | (%) |
| Example 19 | Polyolefine | 71.4 | 31.2 | 50 |
| Example 20 | Polyolefine | 70.7 | 30 | 51 |
| Example 21 | Polyolefine | 70.5 | 44 | 28 |
| Example 22 | Polyester | 79 | 28 | 67 |
| Example 23 | Cellulose | 72.8 | 29.8 | 55 |
| Example 24 | Polyester | 78.3 | 32 | 61 |
| Example 25 | Polyester | 82.7 | 22 | 79 |
| Comparative | Only the | 100 | | 100 |
| example 3 | electrolyte | | | |
| | solution | | | |

The configuration except that of the dye-sensitized photoelectric conversion element is the same as that of the dye-sensitized photoelectric conversion element according to the first embodiment.

### [Method for Producing Dye-Sensitized Photoelectric Conversion Element]

Subsequently, a method for producing the dye-sensitized photoelectric conversion element will be described.

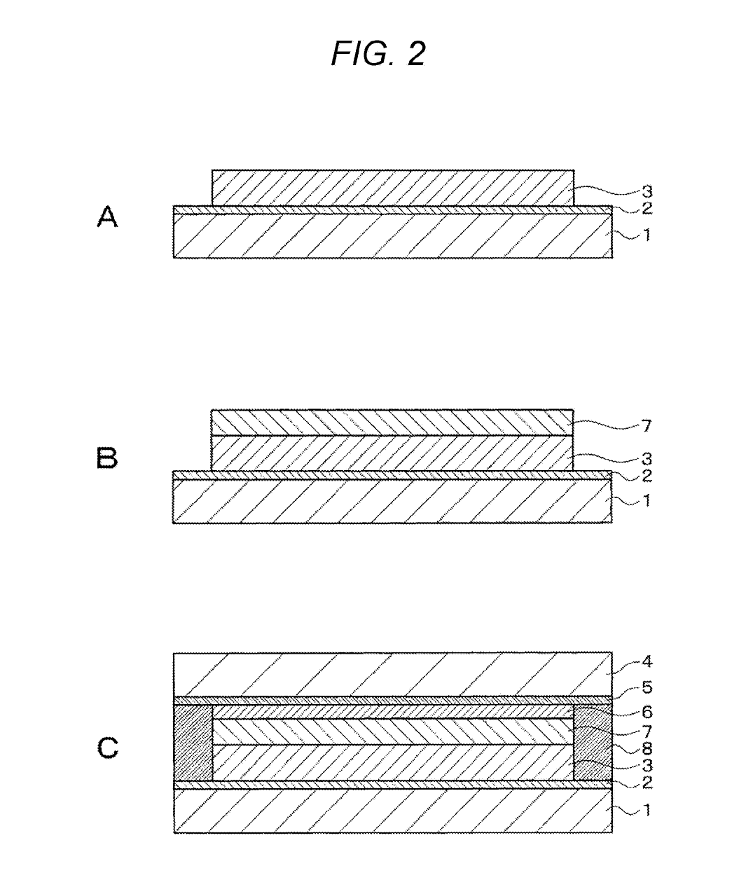

The process is advanced similarly to the first embodiment. As shown in FIG. 2A, a porous electrode 3 to which a photosensitizing dye is bonded is formed on the transparent electrode 2 on the transparent substrate 1.

Subsequently, as shown in FIG. 2B, an electrolyte layer 7 having a porous film containing an electrolyte solution is disposed on the porous electrode 3 on the transparent substrate 1.

Next, as shown in FIG. 2C, the counter substrate 4 is disposed on the electrolyte layer 7, with the counter electrode 6 side down, and thereafter a sealing material 8 is formed at outer peripheral portions of the transparent substrate 1 and the counter substrate 4, thereby sealing the electrolyte layer 7. After the counter substrate 4 is disposed on the electrolyte layer 7, the counter substrate 4 may be pressed against the electrolyte layer 7 to compress the electrolyte layer 7 in a direction perpendicular to the surface thereof, as required. This ensures that when the thickness of the porous film constituting the electrolyte layer 7 is reduced by compression, the electrolyte solution contained in voids of the porous film is pressed out to permeate the porous electrode 3, so that the electrolyte solution is easily distributed throughout the porous electrode 3. The final thickness of the electrolyte layer 7 is, for example, 1 to 100 μm, suitably 1 to 50 μm.

In this manner, the desired dye-sensitized photoelectric conversion element is produced.

### Example 19

Subsequently, the porous polyolefin film preliminarily impregnated with the electrolyte solution was disposed on the porous electrode 3 on the transparent substrate 1. Then, the porous film was compressed in a direction perpendicular to the film surface by a press. The actual porosity of the porous film was 50% and an electrolyte layer 7 was formed. Subsequently, an ionomer resin film and an acrylic UV-curing resin were provided as a sealing material at the outer periphery of the electrolyte layer 7. The counter electrode 6 was disposed on the electrolyte layer 7, and was adhered to the sealing material disposed at the outer periphery of the electrolyte layer 7, to complete the dye-sensitized photoelectric conversion element. The dye-sensitized photoelectric conversion element was produced in the same manner as in Example 8 except the above-described conditions.

### Example 20

A dye-sensitized photoelectric conversion element was produced in the same manner as in Example 19, except that a porous polyolefin film having a porosity of 70.7% and a thickness of 30 μm was used as a porous film to be impregnated with an electrolyte solution, thereby forming an electrolyte layer 7.

### Example 21

A dye-sensitized photoelectric conversion element was produced in the same manner as in Example 19, except that a porous polyolefin film having a porosity of 70.5% and a thickness of 44 μm was used as a porous film to be impregnated with an electrolyte solution, thereby forming an electrolyte layer 7.

### Example 22

A dye-sensitized photoelectric conversion element was produced in the same manner as in Example 19, except that a porous polyester film having a porosity of 79% and a thickness of 28 μm was used as a porous film to be impregnated with an electrolyte solution, thereby forming an electrolyte layer 7.

### Example 23

A dye-sensitized photoelectric conversion element was produced in the same manner as in Example 19, except that a porous cellulose film having a porosity of 72.8% and a thickness of 29.8 μm was used as a porous film to be impregnated with an electrolyte solution, thereby forming an electrolyte layer 7.

### Example 24

A dye-sensitized photoelectric conversion element was produced in the same manner as in Example 19, except that a porous polyester film having a porosity of 78.3% and a thickness of 32 μm was used as a porous film to be impregnated with an electrolyte solution, thereby forming an electrolyte layer 7.

### Example 25

A dye-sensitized photoelectric conversion element was produced in the same manner as in Example 19, except that a porous polyester film having a porosity of 82.7% and a thickness of 22 μm was used as a porous film to be impregnated with an electrolyte solution, thereby forming an electrolyte layer 7.

Table 3 shows collectively the material, porosity, film thickness and actual porosity of the porous film used in forming the electrolyte layer 7 in each of the dye-sensitized photoelectric conversion elements of Examples 19 to 25. Here, the actual porosity of the porous film is represented as follows.

Actual porosity (%)=100−{100−[porosity (%) of film]}×[volume (m³) of film]/{[volume (m³) of electrolyte layer 7]−[bulk volume (m³) of porous electrode 3]}

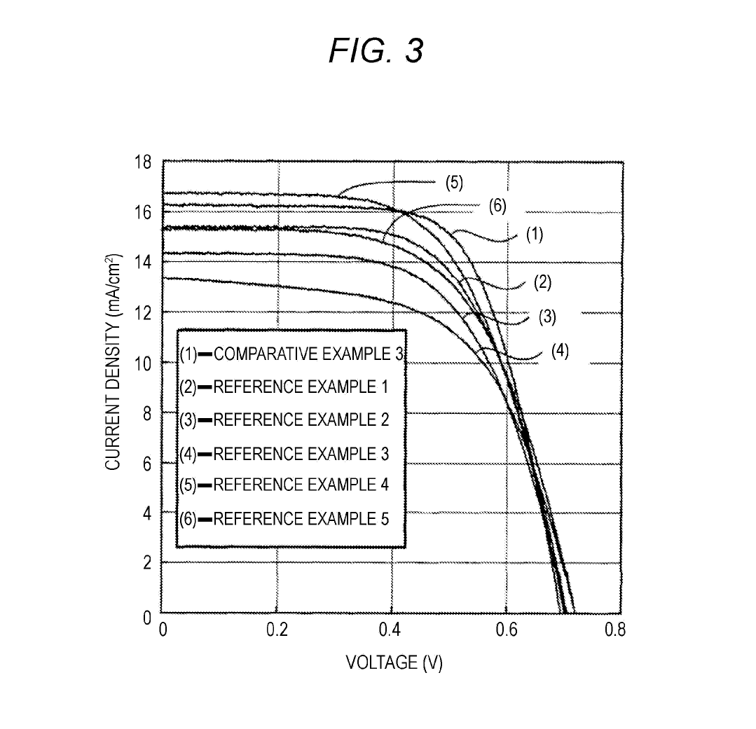

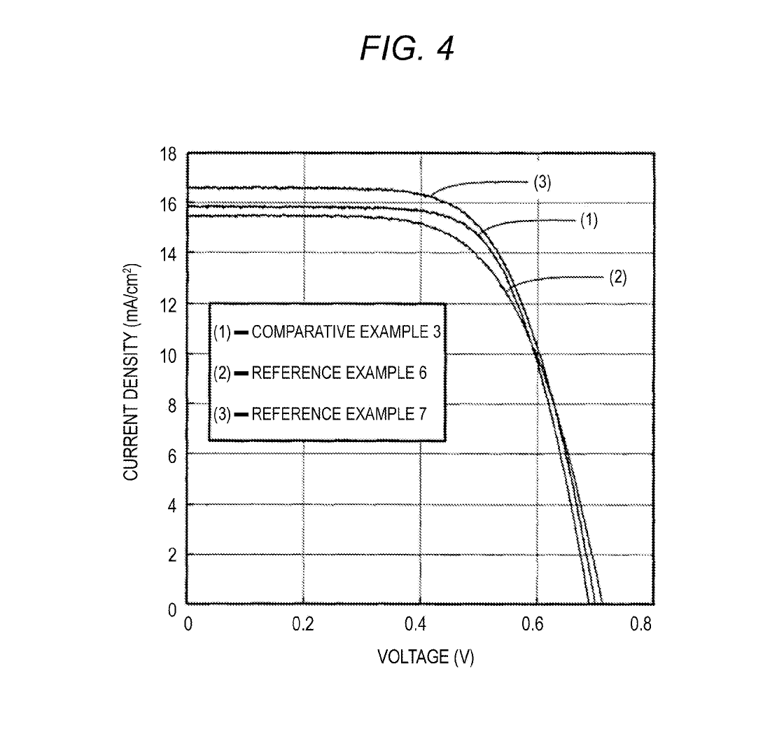

For clearly verifying the effect such that an electrolyte layer 7 has a porous film containing or impregnated with an electrolyte solution, a dye-sensitized photoelectric conversion element was produced by using an electrolyte solution prepared by dissolving 1.0 M of 1-propyl-3-methylimidazolium iodide (MPImI), 0.1 M of iodine I₂, and 0.3 M of N-butylbenzimidazole (NBB) as an additive in 3-methoxypropionitrile (MPN) as solvent in place of the electrolyte solution in Examples 19 to 25. These dye-sensitized photoelectric conversion elements are used as Reference examples 1 to 7 corresponding to Examples 19 to 25. Further, the dye-sensitized photoelectric conversion element of which the electrolyte layer 7 composed only of the electrolyte solution was used in place of the electrolyte layer 7 having a porous film containing or impregnated with an electrolyte solution in Reference examples 1 to 7 is used as Comparative example 3. For the dye-sensitized photoelectric conversion elements in Reference examples 1 to 7 and Comparative example 3, current-voltage characteristics were measured. The measurement was made by irradiating each dye-sensitized photoelectric conversion element with pseudo-sunlight (AM 1.5, 100 mW/cm²). FIGS. 3 and 4 show the measurement results of current-voltage characteristics, for these dye-sensitized photoelectric conversion elements. Tables 4 and 5 show open end voltage V_{oc}, current density J_{sc}, fill factor (FF), photoelectric conversion efficiency (Eff), and internal resistance (Rₛ), for the dye-sensitized photoelectric conversion elements.

TABLE 4

| | Vod | Jsc | FF | Eff | Rs |
|---|---|---|---|---|---|
| Sample | (V) | (mA/cm²) | (%) | (%) | (Ω) |
| Comparative | 0.695 | 16.27 | 67.1 | 7.58 | 38.71 |
| example 3 | | | | | |
| Reference | 0.706 | 15.41 | 62.6 | 6.80 | 45.88 |
| example 1 | | | | | |
| Reference | 0.704 | 14.33 | 61.1 | 6.17 | 51.59 |
| example 2 | | | | | |
| Reference | 0.720 | 13.35 | 59.3 | 5.70 | 58.80 |
| example 3 | | | | | |
| Reference | 0.701 | 16.74 | 60.8 | 7.13 | 45.44 |
| example 4 | | | | | |
| Reference | 0.720 | 15.30 | 60.0 | 6.61 | 53.07 |
| example 5 | | | | | |

TABLE 5

| | Vod | Jsc | FF | Eff | Rs |
|---|---|---|---|---|---|
| Sample | (V) | (mA/cm²) | (%) | (%) | (Ω) |
| Comparative | 0.690 | 15.83 | 67.1 | 7.34 | 39.46 |
| example 3 | | | | | |
| Reference | 0.713 | 15.46 | 62.8 | 6.93 | 47.34 |
| example 6 | | | | | |
| Reference | 0.701 | 16.60 | 64.7 | 7.53 | 40.66 |
| example 7 | | | | | |

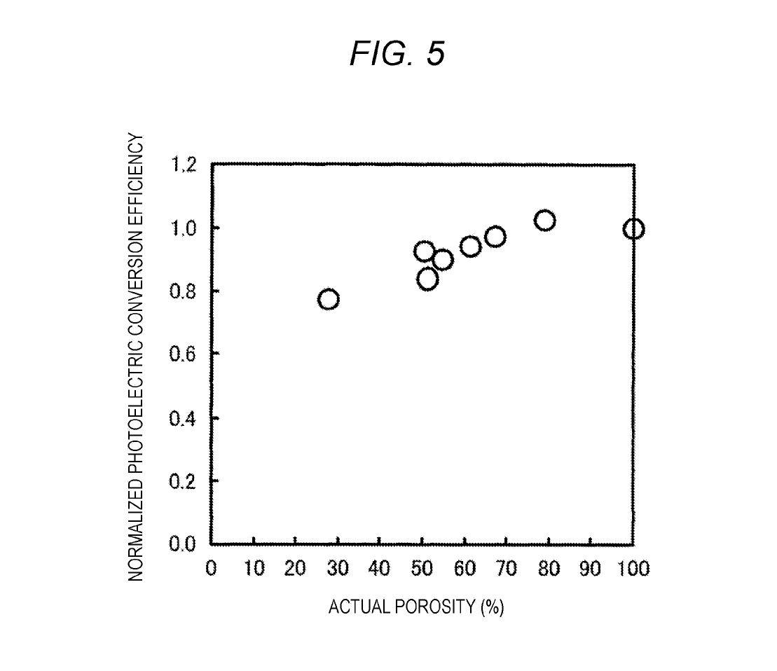

FIG. 5 shows the relationship between the actual porosity of the porous film used in forming the electrolyte layer 7, in each of which the dye-sensitized photoelectric conversion elements in Reference examples 1 to 7, and the normalized photoelectric conversion efficiency, obtained by normalizing the photoelectric conversion efficiency of each of the dye-sensitized photoelectric conversion elements of Reference examples 1 to 7 by the photoelectric conversion efficiency of the dye-sensitized photoelectric conversion element of Comparative Example 3.

From Tables 4 and 5 and FIGS. 3 to 5, it is found that the photoelectric conversion efficiencies of the dye-sensitized photoelectric conversion elements of Reference examples 1 to 7 are, in general, slightly lower than the photoelectric conversion efficiency of the dye-sensitized photoelectric conversion element of Comparative example 3. However, the photoelectric conversion efficiencies of the dye-sensitized photoelectric conversion elements of Reference examples 1, 2, and 4 to 7, in which a porous film with an actual porosity of not less than 50% was used for forming the electrolyte layer 7, are not less than 80% of the photoelectric conversion efficiency of the dye-sensitized photoelectric conversion element of Comparative Example 3. Then, the photoelectric conversion efficiencies of the dye-sensitized photoelectric conversion elements of Reference examples 1, 2, and 4 to 7 show a tendency of increase as the actual porosity of the porous film used in forming the electrolyte layer 7 increases; eventually, the photoelectric conversion efficiencies become comparable to the photoelectric conversion efficiency of the dye-sensitized photoelectric conversion element of Comparative Example 3, when the actual porosity is not less than 80% and less than 100%.

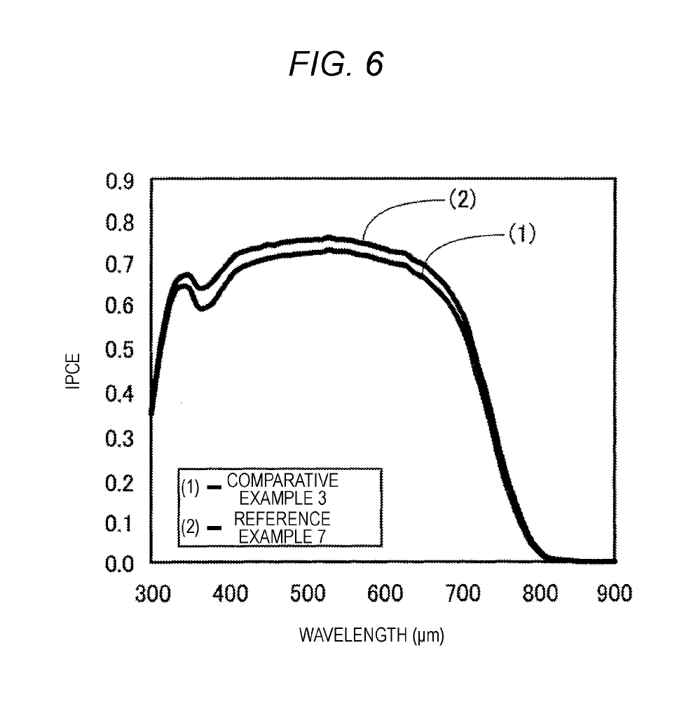

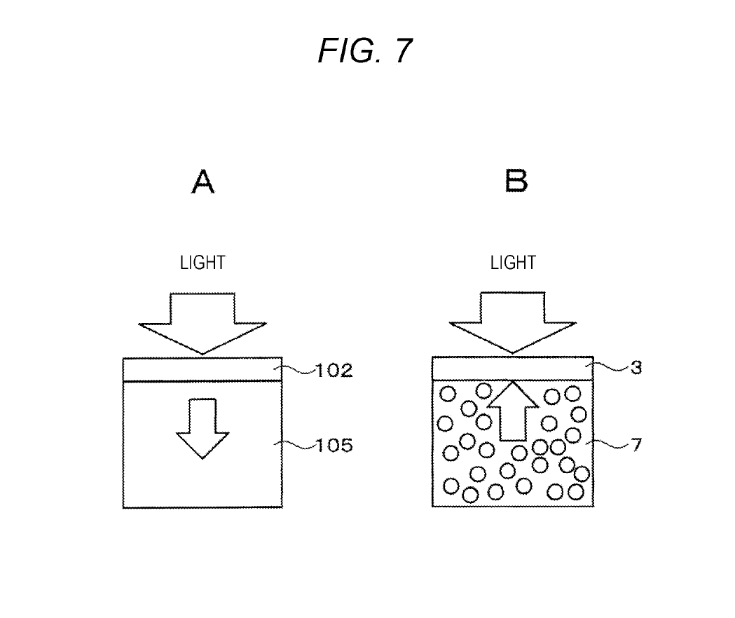

FIG. 6 shows the measurement results of IPCE (Incident Photon-to-current Conversion Efficiency) spectrum for the dye-sensitized photoelectric conversion element of Reference example 7 in which a porous film having an actual porosity of 79% was used in forming the electrolyte layer 7 and for the dye-sensitized photoelectric conversion element of Comparative Example 3 in which the electrolyte layer 7 was formed only from the electrolyte solution. As shown in FIG. 6, it is found that the photoelectric conversion element of Reference example 7 has an increased photoelectric conversion efficiency in the whole wavelength region, as compared with the dye-sensitized photoelectric conversion element of Comparative Example 3. The reason for this is considered as follows. As shown in FIG. 7A, in the dye-sensitized photoelectric conversion element of Comparative Example 3, that portion of the light incident on the porous electrode 102 which fails to be absorbed by the photosensitizing dye is transmitted through the electrolyte layer 105 composed only of the electrolyte solution. On the other hand, in the dye-sensitized photoelectric conversion element of Reference example 7, that portion of the light incident on the porous electrode 3 which fails to be absorbed by the photosensitizing dye and is incident on the electrolyte layer 7 is, because the porous film constituting the electrolyte layer 7 has many voids, effectively scattered by the porous film. The light thus scattered by the electrolyte layer 7 is again incident on the porous electrode 3 from the back side, to be absorbed by the photosensitizing dye. In this case, the light scattered by the porous film contains much component that is obliquely incident on the surface of the porous electrode 3; therefore, the optical path length inside the porous electrode 3 is greatly elongated, leading to an increase in the coefficient of trapping of the incident light by the porous electrode 3. As a result, in the dye-sensitized photoelectric conversion element of Reference example 7, the photoelectric conversion efficiency is increased in the whole wavelength region, as compared with the dye-sensitized photoelectric conversion element of Comparative example 3.

According to the second embodiment, the following merit can be obtained, in addition to the same merits as those obtained in the first embodiment. That is, the electrolyte layer 7 of the dye-sensitized photoelectric conversion element has a porous film containing an electrolyte solution and thus the electrolyte layer 7 is in solid state, which ensures that when the photoelectric conversion element is broken, leakage of the electrolyte solution can be effectively prevented. Further, the porous electrode 3 and the counter electrode 6 are separated from each other by the insulating porous film, which ensures that even if the dye-sensitized photoelectric conversion element is bent, it is possible to prevent electrical insulation performance between the porous electrode 3 and the counter electrode 6 from being lowered. Further, unlike in the case of the conventional dye-sensitized photoelectric conversion element, it becomes unnecessary to provide a liquid pouring hole for pouring the electrolyte solution therethrough, to wipe away the electrolyte solution after pouring the electrolyte solution, or to close the liquid pouring hole. Therefore, the dye-sensitized photoelectric conversion element can be produced easily and simply. Further, since the electrolyte solution can actually be treated as a film, a treatment of the electrolyte solution can be extremely simplified. Therefore, for example in the case of producing a dye-sensitized photoelectric conversion element on a transparent film by a roll-to-roll process, the electrolyte layer 7 having the porous film containing the electrolyte solution can be adhered as a film to the transparent film. Further, in this dye-sensitized photoelectric conversion element, the incident light which fails to be absorbed by the photosensitizing dye adsorbed on the porous electrode 3 is scattered by the electrolyte layer 7, to be again incident on the porous electrode 3. As a result, in this dye-sensitized photoelectric conversion element, it is possible to obtain a high photoelectric conversion efficiency comparable to that of the conventional dye-sensitized photoelectric conversion element in which the electrolyte layer 7 is composed only of the electrolyte solution. Consequently, the use of the excellent dye-sensitized photoelectric conversion element allows a high-performance electronic equipment and the like to be realized.

### 3. Third Embodiment

### Dye-Sensitized Photoelectric Conversion Element

A dye-sensitized photoelectric conversion element according to a third embodiment has the same configuration as the dye-sensitized photoelectric conversion element according to the second embodiment.

### [Method for Producing Dye-Sensitized Photoelectric Conversion Element]

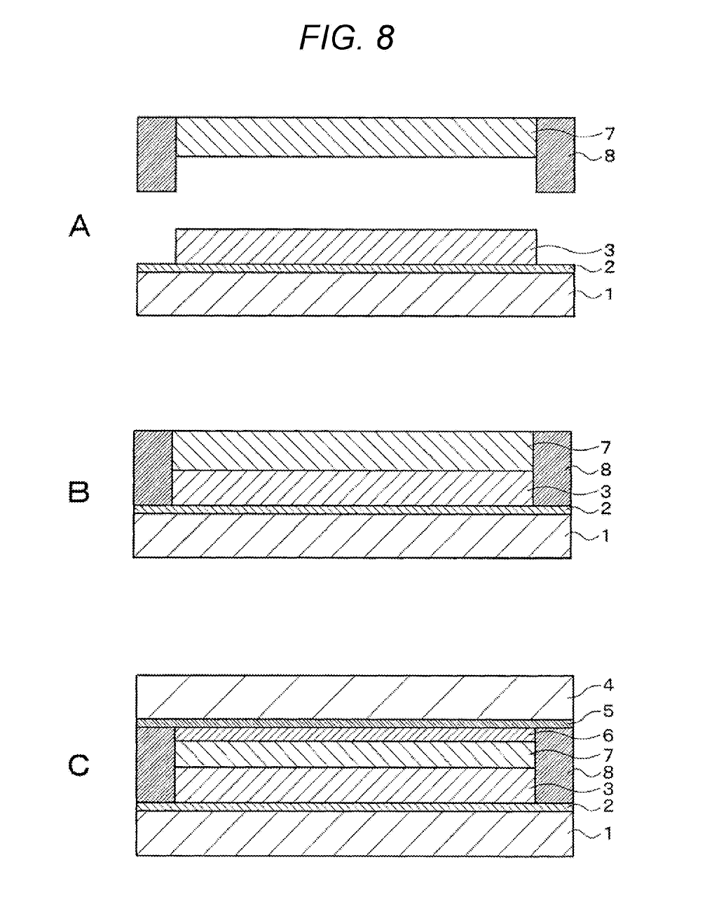

FIGS. 8 A to C show the method for producing a dye-sensitized photoelectric conversion element according to the third embodiment.

As shown in FIG. 8A, in the method for producing the dye-sensitized photoelectric conversion element, first, a porous electrode 3 is formed in the same manner as in the second embodiment.

On the other hand, as shown in FIG. 8A, for example, an integrated film in which a thermosetting sealing material 8 is formed at the outer periphery of and integrally with an electrolyte layer 7 having a porous film containing an electrolyte solution is prepared. The thickness of the electrolyte layer 7 in this state is greater than the thickness of the electrolyte layer 7 in a final state. The thickness of the sealing material 8 is greater than the thickness of the electrolyte layer 7, and is so set that sufficient sealing can be performed by the sealing material 8 finally.

Next, as shown in FIG. 8B, the integrated film in which the sealing material 8 was formed at the outer periphery of the electrolyte layer 7 having the porous film containing the electrolyte solution is disposed on the porous electrode 3.

Subsequently, as shown in FIG. 8C, a counter electrode 6 provided on a counter substrate 4 is disposed on the electrolyte layer 7 and the sealing material 8, the counter substrate 4 is pressed against the electrolyte layer 7 to compress the electrolyte layer 7 in the direction perpendicular to the surface thereof, and the sealing material 8 is cured by heating, to complete sealing. In this case, the thickness of the porous film constituting the electrolyte layer 7 is reduced by the compression; in view of this, such a setting is made that the final actual porosity of the porous film will be a desired value.

In this manner, the desired dye-sensitized photoelectric conversion element is produced.

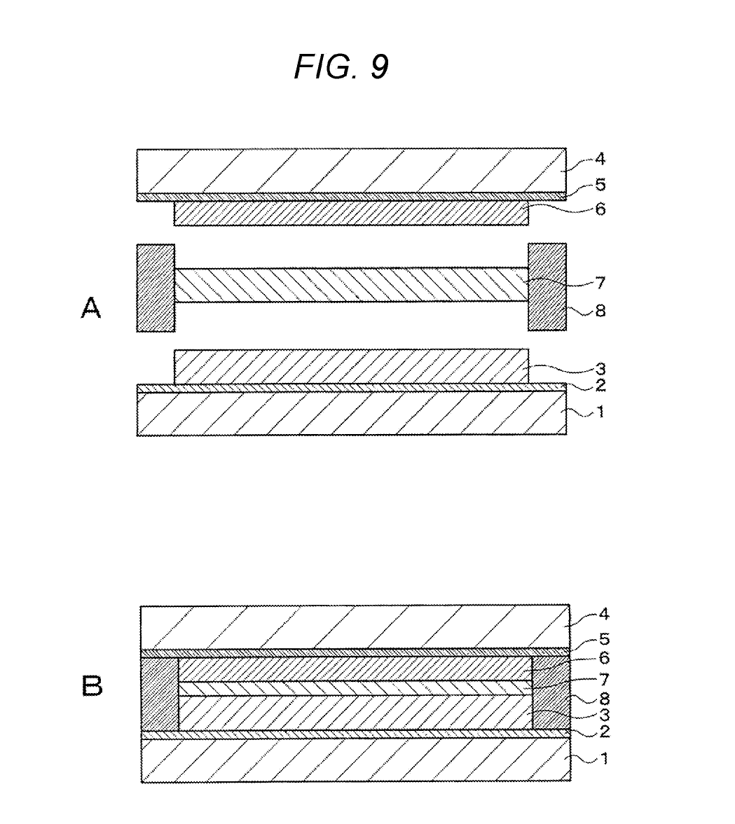

On the other hand, in the case where a bulky (or thick) counter electrode 6 having porous carbon or porous metal is used in the dye-sensitized photoelectric conversion element, the integrated film of the electrolyte layer 7 and the sealing material 8 is formed taking into consideration the bulk of the counter electrode 6, in addition to the bulk of the porous electrode 3. FIGS. 9A and B show a method for producing such a dye-sensitized photoelectric conversion element.

As shown in FIG. 9A, in the method for producing the dye-sensitized photoelectric conversion element, first, a porous film 3 is formed in the same manner as in the second embodiment.

On the other hand, as shown in FIG. 9A, an integrated film in which a thermosetting sealing material 8 is formed at the outer periphery of and integrally with an electrolyte layer 7 having a porous film containing an electrolyte solution is prepared. The thickness of the electrolyte layer 7 in this state is greater than the thickness of the electrolyte layer 7 in a final state. The thickness of the sealing material 8 is greater than the thickness of the electrolyte layer 7, and is so set that sufficient sealing can be performed by the sealing material 8 finally. Additionally, one in which a counter electrode 6 is provided over a counter substrate 4, with a conductive layer 5 therebetween, is prepared.

Next, as shown in FIG. 9B, the integrated film in which the sealing material 8 was formed at the outer periphery of the electrolyte layer 7 having the porous film containing the electrolyte solution is disposed on the porous electrode 3. Subsequently, the counter electrode 6 provided on the counter substrate 4 is disposed on the electrolyte layer 7 and the sealing material 8, and the counter substrate 4 is pressed against the electrolyte layer 7. Thus, the electrolyte layer 7 is compressed in the direction perpendicular to the surface thereof, and the sealing material 8 is cured by heating, to complete sealing. In this case, the thickness of the porous film constituting the electrolyte layer 7 is reduced by the compression; in view of this, such a setting is made that the final actual porosity of the porous film will be a desired value.

In this manner, the desired dye-sensitized photoelectric conversion element is produced.

According to the third embodiment, a merit that the process of forming the sealing material 8 can be omitted and the dye-sensitized photoelectric conversion element can therefore be produced more easily can be obtained, in addition to the same merits as those obtained in the second embodiment.

### 4. Fourth Embodiment

### Dye-Sensitized Photoelectric Conversion Element

A dye-sensitized photoelectric conversion element according to a fourth embodiment differs from the dye-sensitized photoelectric conversion element according to the first embodiment in that a second additive having a pKₐ in the range of 6.04≦pKₐ≦7.3 is added to an electrolyte solution contained in a porous film constituting an electrolyte layer 7, in addition to a first additive. The second additive is a pyridine-based additive, an additive having a heterocyclic ring. Specific examples of the pyridine-based additive include 2-NH2-Py, 4-MeO-Py, and 4-Et-Py. Specific examples of the additive having a heterocyclic ring include MIm, 24-Lu, 25-Lu, 26-Lu, 34-Lu, and 35-Lu.

Further, as solvent of the electrolyte solution contained in the electrolyte layer 7, a solvent having a molecular weight of not less than 47.36 is used. Examples of the solvent include 3-methoxypropionitrile (MPN), methoxyacetonitrile (MAN), and a mixed liquid of acetonitrile (AN) and valeronitrile (VN).

### [Method for Producing Dye-Sensitized Photoelectric Conversion Element]

A method for producing the dye-sensitized photoelectric conversion element is the same as the method for producing the dye-sensitized photoelectric conversion element according to the first embodiment, except that the additive having a pKₐ in the range of 6.04≦pKₐ≦7.3 is added to the electrolyte solution constituting the electrolyte layer 7, in addition to the first additive.

### Example 26

As a first additive, GuOTf was added to the electrolyte solution of Example 1, and 0.054 g of 2-NH2-Py as a second additive was dissolved therein to prepare an electrolyte solution. The dye-sensitized photoelectric conversion element was produced in the same manner as in Example 8 except the above-described conditions.

### Example 27

A dye-sensitized photoelectric conversion element was produced in the same manner as in Example 26, except that an electrolyte solution was prepared using 4-MeO-Py as a second additive.

### Example 28

A dye-sensitized photoelectric conversion element was produced in the same manner as in Example 26, except that an electrolyte solution was prepared using 4-Et-Py as a second additive.

### Example 29

A dye-sensitized photoelectric conversion element was produced in the same manner as in Example 26, except that an electrolyte solution was prepared using MIm as a second additive.

### Example 30

A dye-sensitized photoelectric conversion element was produced in the same manner as in Example 26, except that an electrolyte solution was prepared using 24-Lu as a second additive.

### Example 31

A dye-sensitized photoelectric conversion element was produced in the same manner as in Example 26, except that an electrolyte solution was prepared using 25-Lu as a second additive.

### Example 32

A dye-sensitized photoelectric conversion element was produced in the same manner as in Example 26, except that an electrolyte solution was prepared using 26-Lu as a second additive.

### Example 33

A dye-sensitized photoelectric conversion element was produced in the same manner as in Example 26, except that an electrolyte solution was prepared using 34-Lu as a second additive.

### Example 34

A dye-sensitized photoelectric conversion element was produced in the same manner as in Example 26, except that an electrolyte solution was prepared using 35-Lu as a second additive.

### Comparative Example 4

There was used one obtained by not adding a first additive and a second additive to an electrolyte solution prepared by dissolving 1.0 M of 1-propyl-3-methylimidazolium iodide (MPImI), 0.1 M of iodine I₂, and 0.3 M of N-butylbenzimidazole (NBB) as an additive in 3-methoxypropionitrile (MPN) as solvent in place of the electrolyte solution in Examples 19 to 25. The dye-sensitized photoelectric conversion element was produced in the same manner as in Example 8 except the above-described conditions.

### Comparative Example 5

A dye-sensitized photoelectric conversion element was produced in the same manner as in Comparative example 4, except that an electrolyte solution was prepared using TBP as an additive.

### Comparative Example 6

A dye-sensitized photoelectric conversion element was produced in the same manner as in Comparative example 4, except that an electrolyte solution was prepared using 4-picoline (4-pic) as an additive.

### Comparative Example 7

A dye-sensitized photoelectric conversion element was produced in the same manner as in Comparative example 4, except that an electrolyte solution was prepared using methyl isonicotinate (4-COOMe-Py) as an additive.

### Comparative Example 8

A dye-sensitized photoelectric conversion element was produced in the same manner as in Comparative example 4, except that an electrolyte solution was prepared using 4-cyanopyridine (4-CN-Py) as an additive.

### Comparative Example 9

A dye-sensitized photoelectric conversion element was produced in the same manner as in Comparative example 4, except that an electrolyte solution was prepared using 4-aminopyridine (4-NH2-Py) as an additive.

### Comparative Example 10

A dye-sensitized photoelectric conversion element was produced in the same manner as in Comparative example 4, except that an electrolyte solution was prepared using 4-(methylamino)pyridine (4-MeNH-Py) as an additive.

### Comparative Example 11

A dye-sensitized photoelectric conversion element was produced in the same manner as in Comparative example 4, except that an electrolyte solution was prepared using 3-methoxypyridine (3-MeO-Py) as an additive.

### Comparative Example 12

A dye-sensitized photoelectric conversion element was produced in the same manner as in Comparative example 4, except that an electrolyte solution was prepared using 2-methoxypyridine (2-MeO-Py) as an additive.

### Comparative Example 13

A dye-sensitized photoelectric conversion element was produced in the same manner as in Comparative example 4, except that an electrolyte solution was prepared using methyl nicotinate (3-COOMe-Py) as an additive.

### Comparative Example 14

A dye-sensitized photoelectric conversion element was produced in the same manner as in Comparative example 4, except that an electrolyte solution was prepared using pyridine (Py) as an additive.

### Comparative Example 15

A dye-sensitized photoelectric conversion element was produced in the same manner as in Comparative example 4, except that an electrolyte solution was prepared using 3-bromopyridine (3-Br—Py) as an additive.

### Comparative Example 16

A dye-sensitized photoelectric conversion element was produced in the same manner as in Comparative example 4, except that an electrolyte solution was prepared using N-methylbenzimidazole (NMB) as an additive.

### Comparative Example 17

A dye-sensitized photoelectric conversion element was produced in the same manner as in Comparative example 4, except that an electrolyte solution was prepared using pyrazine as an additive.

### Comparative Example 18

A dye-sensitized photoelectric conversion element was produced in the same manner as in Comparative example 4, except that an electrolyte solution was prepared using thiazole as an additive.

### Comparative Example 19

A dye-sensitized photoelectric conversion element was produced in the same manner as in Comparative example 4, except that an electrolyte solution was prepared using N-methylpyrazole (Me-pyrazole) as an additive.

### Comparative Example 20

A dye-sensitized photoelectric conversion element was produced in the same manner as in Comparative example 4, except that an electrolyte solution was prepared using quinoline as an additive.

### Comparative Example 21

A dye-sensitized photoelectric conversion element was produced in the same manner as in Comparative example 4, except that an electrolyte solution was prepared using isoquinoline as an additive.

### Comparative Example 22

A dye-sensitized photoelectric conversion element was produced in the same manner as in Comparative example 4, except that an electrolyte solution was prepared using 2,2′-bipyridyl (bpy) as an additive.

### Comparative Example 23

A dye-sensitized photoelectric conversion element was produced in the same manner as in Comparative example 4, except that an electrolyte solution was prepared using pyridazine as an additive.

### Comparative Example 24

A dye-sensitized photoelectric conversion element was produced in the same manner as in Comparative example 4, except that an electrolyte solution was prepared using pyrimidine as an additive.

### Comparative Example 25

A dye-sensitized photoelectric conversion element was produced in the same manner as in Comparative example 4, except that an electrolyte solution was prepared using acridine as an additive.

### Comparative Example 26

A dye-sensitized photoelectric conversion element was produced in the same manner as in Comparative example 4, except that an electrolyte solution was prepared using 5,6-benzoquinoline (56-benzoquinoline) as an additive.

For clearly verifying the effect obtained by adding a second additive to an electrolyte solution constituting an electrolyte layer 7, a dye-sensitized photoelectric conversion element was produced by using an electrolyte solution prepared by dissolving 1.0 M of 1-propyl-3-methylimidazolium iodide (MPImI), 0.1 M of iodine I₂, and 0.3 M of N-butylbenzimidazole (NBB) as an additive in 3-methoxypropionitrile (MPN) as solvent in place of the electrolyte solution in Examples 26 to 34. These dye-sensitized photoelectric conversion elements are used as Reference examples 8 to 16 corresponding to Examples 26 to 34.

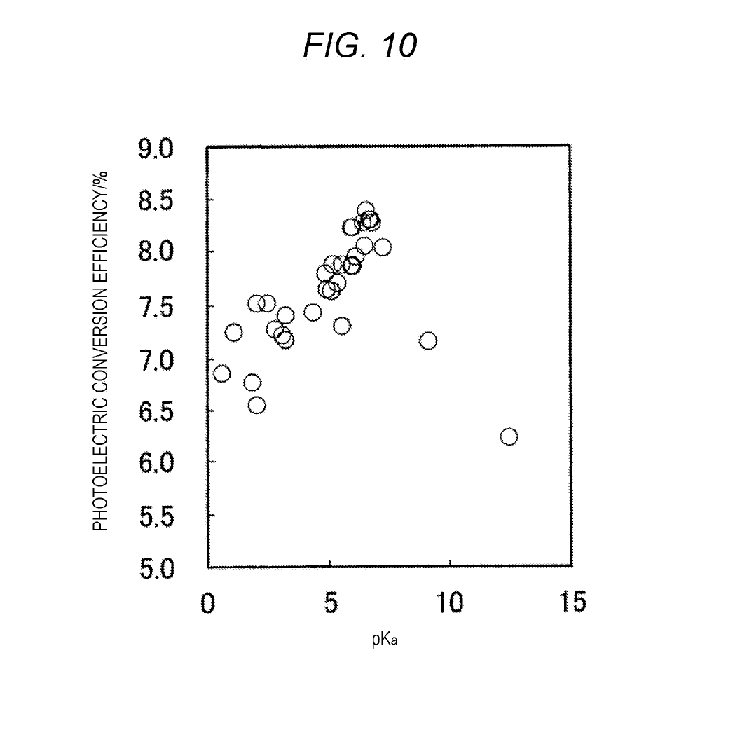

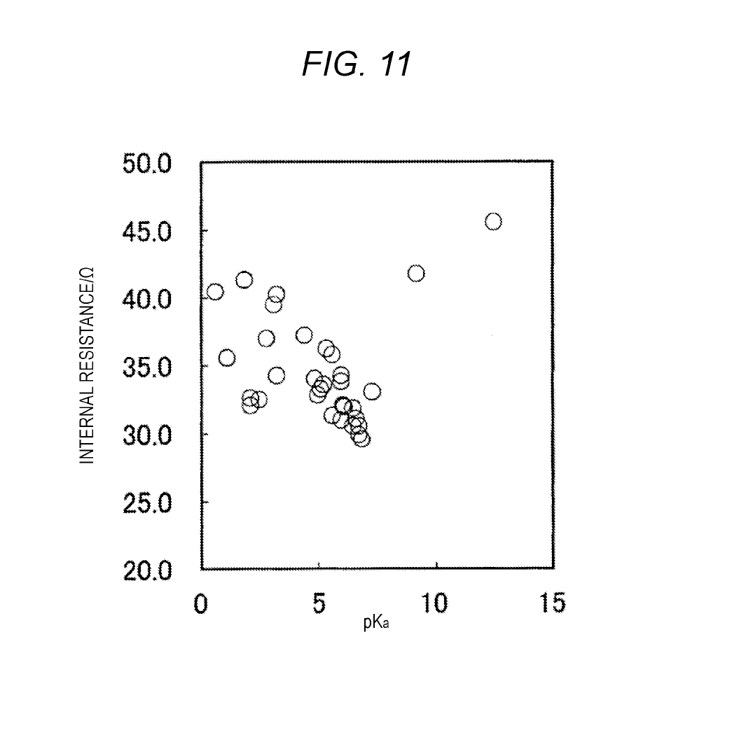

Table 6 shows the pKₐ (water), photoelectric conversion efficiency (Eff), and internal resistance (Rₛ) in Reference examples 8 to 10 and Comparative examples 4 to 15 in each of which a pyridine-based additive was used. Table 7 shows the pKₐ (water), photoelectric conversion efficiency (Eff), and internal resistance (Rₛ) in Reference examples 11 to 16 and Comparative examples 16 to 26 in each of which an additive having a heterocyclic ring was used. From Tables 6 and 7, it is found that, in each of Reference examples 8 to 16 in which an additive having a pKₐ in the range of 6.04≦pKₐ≦7.3 was used, the photoelectric conversion efficiency (Eff) was equivalent or higher and the internal resistance (Rₛ) was lower, as compared with Comparative example 5 in which 4-tert-butylpyridine was used. FIG. 10 shows photoelectric conversion efficiency (Eff) plotted against pKₐ, for Reference examples 8 to 16 and Comparative examples 4 to 26. Further, FIG. 11 shows internal resistance (Rₛ) plotted against pKₐ, for Reference examples 8 to 16 and Comparative Examples 4 to 26.

TABLE 6

| | | pKₐ | Eff | Rs |
|---|---|---|---|---|
| | Additive | (water) | [%] | [Ω] |
| Reference example 8 | 2-NH2—Py | 6.86 | 8.3 | 29.5 |
| Reference example 9 | 4-MeO—Py | 6.62 | 8.4 | 31.0 |
| Reference example 10 | 4-Et—Py | 6.04 | 8.2 | 32.1 |
| Comparative | Without | | 7.1 | 35.5 |
| example 4 | additive | | | |
| Comparative | TBP | 5.99 | 7.9 | 33.8 |
| example 5 | | | | |
| Comparative | 4-pic | 6.03 | 7.9 | 34.3 |
| example 6 | | | | |
| Comparative | 4-COOme—Py | 3.26 | 7.2 | 40.2 |
| example 7 | | | | |
| Comparative | 4-CN—Py | 1.9 | 6.7 | 41.3 |
| example 8 | | | | |
| Comparative | 4-NH2—Py | 9.17 | 7.1 | 41.7 |
| example 9 | | | | |
| Comparative | 4-MeNH—Py | 12.5 | 6.2 | 45.6 |
| example 10 | | | | |
| Comparative | 3-MeO—Py | 4.88 | 7.8 | 34.0 |
| example 11 | | | | |
| Comparative | 2-MeO—Py | 3.28 | 7.4 | 34.3 |
| example 12 | | | | |
| Comparative | 3-COOMe—Py | 3.13 | 7.2 | 39.5 |
| example 13 | | | | |
| Comparative | Py | 5.23 | 7.9 | 33.6 |
| example 14 | | | | |
| Comparative | 3-Br—Py | 2.84 | 7.3 | 36.9 |
| example 15 | | | | |

TABLE 7

| | Additive | pKₐ (water) | Eff [%] | Rs [Ω] |
|---|---|---|---|---|
| Reference example 11 | Mlm | 7.3 | 8.0 | 33.0 |
| Reference example 12 | 24-Lu | 6.72 | 8.3 | 29.9 |
| Reference example 13 | 25-Lu | 6.47 | 8.3 | 30.5 |
| Reference example 14 | 26-Lu | 6.77 | 8.3 | 30.6 |
| Reference example 15 | 34-Lu | 6.52 | 8.0 | 31.9 |
| Reference example 16 | 35-Lu | 6.14 | 7.9 | 32.0 |
| Comparative example | NMB | 5.6 | 7.9 | 35.8 |
| 16 | | | | |
| Comparative example | pyrazine | 0.6 | 6.8 | 40.4 |
| 17 | | | | |
| Comparative example | thiazole | 2.5 | 7.5 | 32.5 |
| 18 | | | | |
| Comparative example | Me-pyrazole | 2.1 | 7.5 | 32.7 |
| 19 | | | | |
| Comparative example | quinoline | 4.97 | 7.6 | 32.9 |
| 20 | | | | |
| Comparative example | isoquinoline | 5.38 | 7.7 | 36.1 |
| 21 | | | | |
| Comparative example | bpy | 4.42 | 7.4 | 37.2 |
| 22 | | | | |
| Comparative example | pyridazine | 2.1 | 6.5 | 32.0 |
| 23 | | | | |
| Comparative example | pyrimidine | 1.1 | 7.2 | 35.5 |
| 24 | | | | |
| Comparative example | acridine | 5.6 | 7.3 | 31.3 |
| 25 | | | | |
| Comparative example | 56- | 5.15 | 7.6 | 33.3 |
| 26 | benzoquinoline | | | |

Subsequently, the dependency of the effect of the second additive added to the electrolyte solution on the kind of solvent of the electrolyte solution will be described.

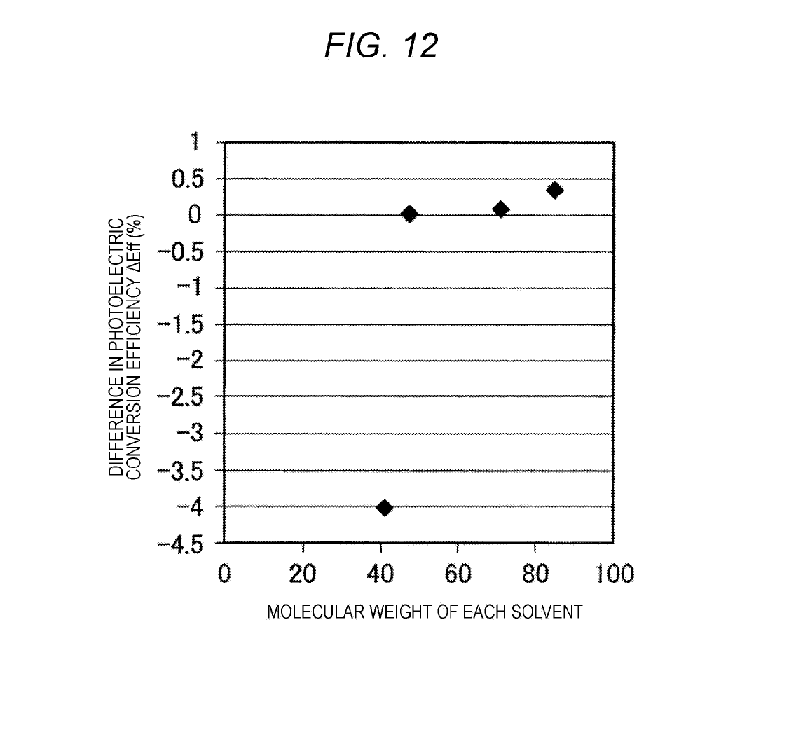

The effect of the second additive was confirmed on the basis of each of the solvents differing in molecular weight. Here, 4-tert-butylpyridine (TBP) and 4-Et-Py (4-ethylpyridine), which have comparatively close pKₐ values, were made to be objects of comparison. The evaluation method is as follows. The photoelectric conversion efficiency (Eff(4-Et-Py)) of the dye-sensitized photoelectric conversion element using 4-Et-Py as a second additive to the electrolyte solution and the photoelectric conversion efficiency (Eff(TBP)) of the dye-sensitized photoelectric conversion element using TBP as a second additive to the electrolyte solution are measured, on the basis of each of the solvents. Then, the difference ΔEff=Eff(4-Et-Py)−Eff(TBP) between these photoelectric conversion efficiencies is used as an index of the effect. As the solvent of the electrolyte solution, four solvents consisting of acetonitrile (AN), a mixed liquid of acetonitrile (AN) and valeronitrile (VN), methoxyacetonitrile (MAN) and 3-methoxypropionitrile (MPN) were used. Table 8 shows molecular weight, Eff(4-Et-Py), Eff(TBP) and ΔEff, for each of the solvents. In this regard, the values of Eff(4-Et-Py), Eff(TBP), and ΔEff for acetonitrile (AN) were obtained by reference to those reported in Solar Energy Materials & Solar Cells, 2003, 80, 167. FIG. 12 shows the difference in photoelectric conversion efficiency, ΔEff, plotted against the molecular weight of the solvents.

TABLE 8

| | Molecular | | Eff | |
|---|---|---|---|---|
| Solvent | weight | Eff (4-Et—Py) | (TBP) | ΔEff |
| AN | 41.05 | 3.4 | 7.4 | −4 |
| AN/VN | 47.36 | 8.72 | 8.69 | 0.03 |
| MAN | 71.08 | 8.05 | 7.96 | 0.09 |
| MPN | 85.1 | 8.22 | 7.86 | 0.36 |

From Table 8 and FIG. 12, it is found that the molecular weight range for ΔEff>0, in other words, the molecular weight range in which Eff(4-Et-Py) is greater than Eff(TBP), is not less than 47.36. In this regard, the value of 47.36 is an apparent molecular weight calculated using mixing volume fractions in the mixed liquid of acetonitrole (AN) and valeronitrile (VN).

As seen from the foregoing, it can be said that the use of an additive having a pKₐ in the range of 6.04≦pKₐ≦7.3 as the second additive to the electrolyte solution is effective, in the cases of the solvents having molecular weights of not less than 47.36.

As described above, according to the fourth embodiment, a second additive having a pKₐ in the range of 6.04≦pKₐ≦7.3 is used as the additive to the electrolyte solution constituting the electrolyte layer 7, so that the following merits can be obtained, in addition to the same merits as those obtained in the first embodiment. That is, an equivalent or higher photoelectric conversion efficiency and an equivalent or lower internal resistance can be obtained, as compared with the conventional dye-sensitized photoelectric conversion element in which 4-tert-butylpyridine is used as the additive to the electrolyte solution. Consequently, a dye-sensitized photoelectric conversion element having excellent photoelectric conversion characteristics can be obtained. Further, since there are a variety of second additives which have a pKₐ in the range of 6.04≦pKₐ≦7.3, the choice of second additive is extremely broad.

### 5. Fifth Embodiment

### Dye-Sensitized Photoelectric Conversion Element

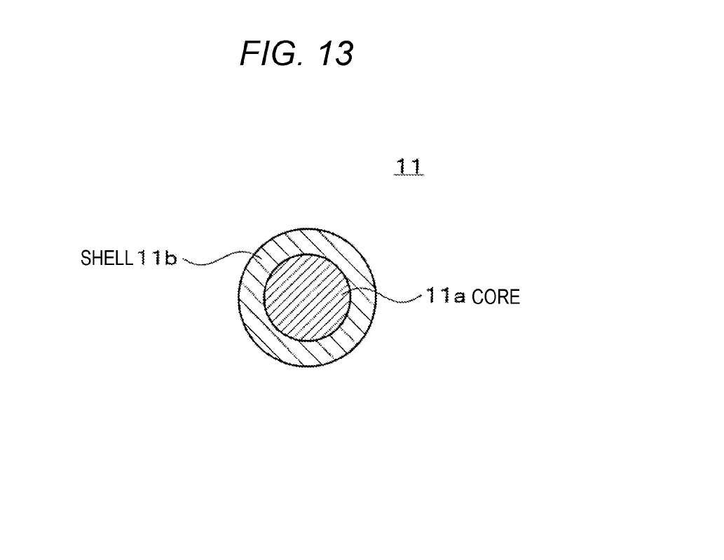

In a dye-sensitized photoelectric conversion element according to a fifth embodiment, a porous electrode 13 has metal/metal oxide particles, typically, a sintered body of metal/metal oxide particles. FIG. 13 shows in detail the structure of the metal/metal oxide particle 11. As shown in FIG. 13, the metal/metal oxide particle 11 has a core/shell structure which includes a spherical core 11a having a metal and a shell 11b having a metal oxide surrounding the core 11a. One or more photosensitizing dyes (not shown) are bonded to (or adsorbed on) the surfaces of the metal oxide shells 11b of the metal/metal oxide particles 11.

Examples of the metal oxide constituting the shells 11b of the metal/metal oxide particles 11 include titanium oxide (TiO₂), tin oxide (SnO₂), niobium oxide (Nb₂O₅), and zinc oxide (ZnO). Among these metal oxides, TiO₂ (particularly anatase-type TiO₂) is preferred for use. However, the metal oxide is not limited to these examples, and two or more of the metal oxides may be used as a mixture or a composite material, as required. Further, the form of the metal/metal oxide particles 11 may be any of granular form, tubular form, rod-like form, and the like.

The particle diameter of the metal/metal oxide particles 11 is not particularly limited. Generally, the particle diameter in terms of average particle diameter of primary particles is 1 to 500 nm, preferably 1 to 200 nm, particularly preferably 5 to 100 nm. Further, the particle diameter of the cores 11a of the metal/metal oxide particles 11 is generally 1 to 200 nm.

The configuration except that of the dye-sensitized photoelectric conversion element is the same as that of the dye-sensitized photoelectric conversion element according to the first embodiment.

### [Method for Producing Dye-Sensitized Photoelectric Conversion Element]

A method for producing the dye-sensitized photoelectric conversion element is the same as the method for producing the dye-sensitized photoelectric conversion element according to the first embodiment, except that the porous electrode 3 is formed of the metal/metal oxide particles 11.

The metal/metal oxide particles 11 constituting the porous electrode 3 can be prepared by a conventionally known method (see, for example, Jpn. J. Appl. Phys., Vol. 46, No. 4B, 2007, pp. 2567-2570). As an example, a method for producing metal/metal oxide particles 11 in which the core 11a has Au and the shell 11b has TiO₂ will be outlined as follows. First, dehydrated trisodium citrate is added to 500 mL of heated 5×10⁻⁴ M HAuCl₄ solution, followed by stirring. Next, mercaptoundecanoic acid is added to an aqueous ammonia solution in an amount of 2.5 wt %, followed by stirring, then the resulting solution is added to the Au nanoparticle dispersion, and the admixture is warmed for 2 hours. Subsequently, 1 M HCl is added to the resulting solution, to adjust the pH to 3. Next, titanium isopropoxide and triethanolamine are added to the Au colloidal solution in a nitrogen atmosphere. Thus, the metal/metal oxide particles 11 in which the core 11a has Au and the shell 11b has TiO₂ are prepared.

### [Operation of Dye-Sensitized Photoelectric Conversion Element]

Subsequently, operation of the dye-sensitized photoelectric conversion element will be described.

The dye-sensitized photoelectric conversion element, upon incidence of light thereon, operates as a cell with the counter electrode 6 as a positive electrode and with the transparent electrode 2 as a negative electrode. The principle of the operation is as follows. Here, it is assumed that FTO is used as the material for the transparent electrode 2, while Au is used as the material for the cores 11 metal/metal oxidea of the particles 11 constituting the porous electrode 3, TiO₂ is used as the material for the shells 11b, and oxidation-reduction species of I⁻/I₃⁻ are used as a redox pair. However, it is not limited thereto.

When photons transmitted through the transparent substrate 1 and the transparent electrode 2 and incident on the porous electrode 3 are absorbed by the photosensizing dye bonded to the porous electrode 3, electrons in the photosensitizing dye are excited from the ground state (HOMO) to the excited state (LUMO). The electrons thus excited are drawn through the electrical bonding between the photosensitizing dye and the porous electrode 3 into the conduction band of TiO₂ constituting the shells 11b of the metal/metal oxide particles 11 constituting the porous electrode 3, and pass through the porous electrode 3, to reach the transparent electrode 2. In addition, light is incident on the surfaces of the Au cores 11a of the metal/metal oxide particles 11, whereby localized surface plasmon is excited, to produce a field intensifying effect. By the field intensification, a large amount of electrons are excited into the conduction band of TiO₂ constituting the shells 11b, and the electrons pass through the porous electrode 3, to reach the transparent electrode 2. Thus, when light is incident on the porous electrode 3, not only the electrons generated by excitation of the photosensitizing dye reach the transparent electrode 2, but also the electrons excited into the conduction band of TiO₂ constituting the shells 11b by excitation of the localized surface plasmon at the surfaces of the cores 11a of the metal/metal oxide particles 11 reach the transparent electrode 2. Consequently, a high photoelectric conversion efficiency can be obtained.

On the other hand, the photosensitizing dye having lost the electrons accepts electrons from a reducing agent, for example, I⁻ present in the electrolyte layer 7 through the following reaction, and produces an oxidizing agent, for example, I₃⁻ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above reaction, and is thereby reduced to the original reducing agent.

I₃⁻→I₂+I⁻

I₂+2e⁻→2I⁻

The electrons sent out from the transparent electrode 2 to an external circuit perform an electrical work in the external circuit, and thereafter return to the counter electrode 6. In this manner, optical energy is converted into electrical energy, without leaving any change in either of the photosensitizing dye and the electrolyte layer 7.

According to the fifth embodiment, the following merit can be obtained, in addition to the same merits as those obtained in the first embodiment. That is, the porous electrode 3 has the metal/metal oxide particles 11 having the core/shell structure which includes the spherical core 11a having a metal and the shell 11b having a metal oxide surrounding the core 11a. Therefore, when the space between the porous electrode 3 and the counter electrode 6 is filled with the electrolyte layer 7, the electrolyte of the electrolyte layer 7 does not make contact with the metal cores 11a of the metal/metal oxide particles 11, so that the porous electrode 11 can be prevented from being dissolved by the electrolyte. Accordingly, metals having a high surface plasmon effect, such as gold, silver, and copper can be used as the metal constituting the cores 11a of the metal/metal oxide particles 11, whereby the surface plasmon resonance effect can be sufficiently obtained. Further, an iodine electrolyte can be used as the electrolyte of the electrolyte layer 7. In this manner, it is possible to obtain a dye-sensitized photoelectric conversion element having a high photoelectric conversion efficiency. Consequently, the use of the excellent dye-sensitized photoelectric conversion element allows a high-performance electronic equipment to be realized.

### 6. Sixth Embodiment

### Photoelectric Conversion Element

A photoelectric conversion element according to a sixth embodiment has the same configuration as that of the dye-sensitized photoelectric conversion element according to the fifth embodiment, except that no photosensitizing dye is bonded to metal/metal oxide particles 11 constituting a porous electrode 3.

### [Method for Producing Photoelectric Conversion Element]

A method for producing the dye-sensitized photoelectric conversion element is the same as the method for producing the dye-sensitized photoelectric conversion element according to the fifth embodiment, except that no photosensitizing dye is adsorbed on the porous electrode 3.

### [Operation of Photoelectric Conversion Element]

Subsequently, operation of the photoelectric conversion element will be described.

The photoelectric conversion element, upon incidence of light thereon, operates as a cell with the counter electrode 6 as a positive electrode and with the transparent electrode 2 as a negative electrode. The principle of the operation is as follows. Here, it is assumed that FTO is used as the material for the transparent electrode 2, while Au is used as the material for the cores 11 metal/metal oxidea of the particles 11 constituting the porous electrode 3, TiO₂ is used as the material for the shells 11b, and oxidation-reduction species of I⁻/I₃⁻ are used as a redox pair. However, it is not limited thereto.

When light is transmitted through the transparent substrate 1 and the transparent electrode 2 and is incident on the surfaces of the Au cores 11a of the metal/metal oxide particles 11 constituting the porous electrode 3, whereby localized surface plasmon is excited, to produce a By the field intensification, a large amount of electrons are excited into the conduction band of TiO₂ constituting the shells 11b, and the electrons pass through the porous electrode 3, to reach the transparent electrode 2.

On the other hand, the porous electrode 3 having lost the electrons accepts electrons from a reducing agent, for example, I⁻ present in the electrolyte layer 7 through the following reaction, and produces an oxidizing agent, for example, I₃⁻ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above reaction, and is thereby reduced to the original reducing agent.

I₃⁻→I₂+I⁻

I₂+2e⁻→2I⁻

The electrons sent out from the transparent electrode 2 to an external circuit perform an electrical work in the external circuit, and thereafter return to the counter electrode 6. In this manner, optical energy is converted into electrical energy, without leaving any change in either of the photosensitizing dye and the electrolyte layer 7.

According to the sixth embodiment, the same merit as those obtained in the first embodiment can be obtained.

While the embodiments and the examples have been specifically described above, the present disclosure is not limited to the embodiments and the examples, and various modifications are possible.

For example, the numerical values, structures, configurations, shapes, materials, etc. described in the embodiments and examples are merely examples, so that numerical values, structures, configurations, shapes, materials, etc., different from the above-described may also be adopted, as required.

### REFERENCE SIGNS LIST

1 Transparent substrate
2 Transparent electrode
3 Porous electrode
4 Counter substrate
5 Conductive layer
6 Counter electrode
7 Electrolyte layer
8 Sealing material
11 Metal/metal oxide particles
11a Core
11b Shell

1. A photoelectric conversion element comprising a structure in which an electrolyte layer is formed between a porous electrode and a counter electrode, wherein at least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is added to the electrolyte layer.

2. The photoelectric conversion element according to claim 1, wherein the electrolyte layer has a porous film containing an electrolyte solution.

3. The photoelectric conversion element according to claim 2, wherein the porous film has a non-woven fabric.

4. The photoelectric conversion element according to claim 3, wherein the non-woven fabric has polyolefine, polyester or cellulose.

5. The photoelectric conversion element according to claim 4, wherein the porous film has a porosity of not less than 80% and less than 100%.

6. The photoelectric conversion element according to claim 5, wherein a second additive having a pKₐ in the range of 6.04≦pKₐ≦7.3 is added to the electrolyte solution and/or a second additive having a pKₐ in the range of 6.04≦pKₐ≦7.3 is adsorbed on that surface of at least one of the porous electrode and the counter electrode which faces the electrolyte layer.

7. The photoelectric conversion element according to claim 6, wherein the second additive is a pyridine-based additive or an additive having a heterocyclic ring.

8. The photoelectric conversion element according to claim 7, wherein the second additive is at least one selected from the group consisting of 2-aminopyridine, 4-methoxypyridine, 4-ethylpyridine, N-methylimidazole, 2,4-lutidine, 2,5-lutidine, 2,6-lutidine, 3,4-lutidine, and 3,5-lutidine.

9. The photoelectric conversion element according to claim 6, wherein a solvent of the electrolyte solution has a molecular weight of not less than 47.36.

10. The photoelectric conversion element according to claim 9, wherein the solvent is 3-methoxypropionitrile, methoxyacetonitrile, or a mixed liquid of acetonitrile and valeronitrile.

11. The photoelectric conversion element according to claim 1, wherein the photoelectric conversion element is a dye-sensitized photoelectric conversion element having a photosensitizing dye bonded to the porous electrode.

12. The photoelectric conversion element according to claim 11, wherein the porous electrode is composed of fine particles of a semiconductor.

13. The photoelectric conversion element according to claim 1, wherein the electrolyte layer contains an electrolyte solution, and a solvent of the electrolyte solution contains an ionic liquid having an electron-acceptive functional group and an organic solvent having an electron-donative functional group.

14. The photoelectric conversion element according to claim 1, wherein the porous electrode is composed of particles each of which includes a core having a metal and a shell having a metal oxide surrounding the core.

15. A method for producing a photoelectric conversion element comprising: forming a structure in which an electrolyte layer obtained by adding at least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is provided between a porous electrode and a counter electrode.

16. An electronic equipment comprising:
at least one photoelectric conversion element, wherein the photoelectric conversion element has a structure in which an electrolyte layer is formed between a porous electrode and a counter electrode, and at least one first additive selected from the group consisting of GuOTf, EMImSCN, EMImOTf, EMImTFSI, EMImTfAc, EMImDINHOP, EMImMeSO₃, EMImDCA, EMImBF₄, EMImPF₆, EMImFAP, EMImEt₂PO₄, and EMImCB₁₁H₁₂ is added to the electrolyte layer.

17. A photoelectric conversion element comprising:
a structure in which an electrolyte layer is formed between a porous electrode and a counter electrode, wherein at least one of first additives (except for GuSCN) having one of cations represented by Formula (1), (2) or (3) below and anions below is added to the electrolyte layer:
(A) Cation 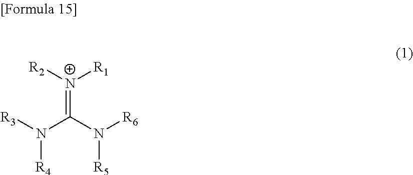
R₁ to R₆═H, or a hydrocarbon having 1 to 20 carbon(s) 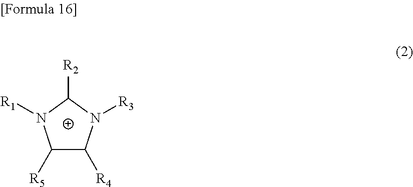
R₁ to R₅═H, or a hydrocarbon having 1 to 20 carbon(s) 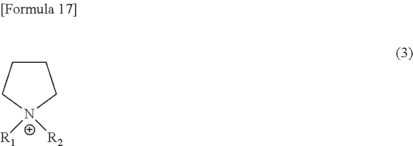
R₁ to R₂═H, or a hydrocarbon having 1 to 20 carbon(s)
(B) Anion
SCN, [DCA], BF₄, PF₆, [TfAc], [OTf], [TFSI], [MeSO₃], [MeOSO₃], [HS O₄], [FAP], [DA], [DPA], [DINHOP], [FSI], [DEPA], [cheno], [Et₂PO₄], CB₁₁H₁₂, [COSAN], [cyclicTFSI], C₂F₅SO₃, C₃F₇SO₃, C₄F₉SO₃, N(C₃F₇SO₂)₂, N(C₄F₉SO₂)₂, fluorine, chlorine, bromine, and iodine.
